(19) United States
(12) Patent Application Publication
(10) Pub. No.: US 2011/0280266 A1
(43) Pub. Date: Nov. 17, 2011

(54) SEMICONDUCTOR LASER APPARATUS, METHOD OF MANUFACTURING SEMICONDUCTOR LASER APPARATUS AND OPTICAL APPARATUS

(75) Inventors: Nobuhiko HAYASHI, Osaka (JP); Hideki YOSHIKAWA, Takarazuka-shi (JP); Keiichi KURAMOTO, Osaka (JP); Yasuhiko NOMURA, Osaka (JP); Takenori GOTO, Osaka (JP); Yoshio OKAYAMA, Moriyama-shi (JP); Seiichi TOKUNAGA, Osaka (JP)

(73) Assignee: SANYO ELECTRIC CO., LTD., Moriguchi-shi (JP)

(21) Appl. No.: 13/106,123

(22) Filed: May 12, 2011

(30) Foreign Application Priority Data
May 14, 2010 (JP) JP2010-112231
May 31, 2010 (JP) JP2010-123965
Aug. 4, 2010 (JP) JP2010-175647
Feb. 28, 2011 (JP) JP2011-041230

(51) Int. Cl. H01S 5/022; H01L 21/52

(52) U.S. Cl. 372/43.01; 438/26; 257/E21.5

(57) ABSTRACT

This semiconductor laser apparatus includes a semiconductor laser chip and a package sealing the semiconductor laser chip. The package has a base portion mounted with the semiconductor laser chip, a sealing member and a window member. The semiconductor laser chip is sealed with the base portion, the sealing member and the window member. At least two of the base portion, the sealing member and the window member are bonded to each other through a sealant made of an ethylene-polyvinyl alcohol copolymer.

### CROSS-REFERENCE TO RELATED APPLICATION

The priority application numbers JP2010-112231, Semiconductor Laser Apparatus and Optical Apparatus, May 14, 2010, Nobuhiko Hayashi, JP2010-123965, Semiconductor Laser Apparatus and Optical Apparatus, May 31, 2010, Hideki Yoshikawa et al., JP2010-175647, Semiconductor Laser Apparatus, Method of Manufacturing Semiconductor Laser Apparatus and Optical Apparatus, Aug. 4, 2010, Nobuhiko Hayashi et al., and JP2011-041230, Semiconductor Laser Apparatus, Method of Manufacturing Semiconductor Laser Apparatus and Optical Apparatus, Feb. 28, 2011, Nobuhiko Hayashi et al., upon which this patent application is based are hereby incorporated by reference.

### BACKGROUND OF THE INVENTION

1. Field of the Invention

The present invention relates to a semiconductor laser apparatus, a method of manufacturing a semiconductor laser apparatus and an optical apparatus, and more particularly, it relates to a semiconductor laser apparatus comprising a package sealing a semiconductor laser chip, a method of manufacturing the semiconductor laser apparatus and an optical apparatus employing the same.

2. Description of the Background Art

A semiconductor laser device has been widely applied as a light source for an optical disc system, an optical communication system or the like in general. For example, an infrared semiconductor laser device emitting a laser beam having a wavelength of about 780 nm has been put into practice as a light source for reading of a CD, and a red semiconductor laser device emitting a laser beam having a wavelength of about 650 nm has been put into practice as a light source for writing/reading of a DVD. A blue-violet semiconductor laser device emitting a laser beam having a wavelength of about 405 nm has been put into practice as a light source for a Blu-ray disc.

In order to attain such a light source apparatus, a semiconductor laser apparatus comprising a package sealing a semiconductor laser chip is known in general, as disclosed in each of Japanese Patent Laying-Open Nos. 9-205251 (1997), 10-209551 (1998) and 2009-135347, for example.

Japanese Patent Laying-Open No. 9-205251 (1997) discloses a plastic-molded apparatus of a semiconductor laser comprising a header formed with a flange surface and made of a resin product, a semiconductor laser chip mounted on the header and a transparent cap of resin covering the periphery of the semiconductor laser chip. In this plastic-molded apparatus, an edge of an opening of the transparent cap is bonded onto the flange surface of the header through an adhesive containing an epoxy resin-based material, whereby the semiconductor laser chip is hermetically sealed.

Japanese Patent Laying-Open No. 10-209551 (1998) discloses a semiconductor laser apparatus comprising a header made of a resin product, a semiconductor laser chip mounted on a chip set portion of the header and a transparent cap (lid member) of resin having an L-shaped cross section. In this semiconductor laser apparatus, an outer edge of the transparent cap is bonded to the chip set portion of the header through a photosetting adhesive or the like, whereby the semiconductor laser chip is hermetically sealed.

Japanese Patent Laying-Open No. 2009-135347 discloses an optical module comprising a substrate made of a metal material, a surface-emitting laser chip mounted on an upper surface of the substrate and a package member (sealing member) made mainly of a metal-based material, sealing space in the periphery of a laser beam source. In this optical module, an edge of an opening of the package member is bonded onto the upper surface of the substrate through a bonding film, whereby the surface-emitting laser chip is hermetically sealed. The bonding film is formed through a special manufacturing process in which hydrogen atoms or the like are introduced as an elimination group into a metal oxide such as indium tin oxide (ITO), indium zinc oxide (IZO) or antimony tin oxide (ATO).

However, in the semiconductor apparatus disclosed in each of Japanese Patent Laying-Open Nos. 9-205251 (1997) and 10-209551 (1998), the epoxy resin-based adhesive, or the photosetting adhesive or the like is employed to bond the header and the transparent cap to each other. When these adhesives contain many volatile gas components such as organic gas especially before being hardened, a package may be filled with the aforementioned volatile gas after bonding. In this case, an adherent substance is easily formed on a laser emitting facet of the semiconductor laser chip by exciting and degrading the volatile gas by a high-energy laser beam having a short lasing wavelength especially when a blue-violet semiconductor laser chip is sealed. In this case, the adherent substance absorbs the laser beam, and hence the temperature of the laser emitting facet is easily increased. Consequently, the semiconductor laser chip is disadvantageously deteriorated.

In the optical module (semiconductor apparatus) disclosed in Japanese Patent Laying-Open No. 2009-135347, the package and the substrate are bonded to each other with the bonding film after the bonding film made of the metal oxide with an elimination group is formed through the prescribed manufacturing process, and hence a manufacturing process is disadvantageously complicated.

### SUMMARY OF THE INVENTION

In order to attain the aforementioned objects, a semiconductor laser apparatus according to a first aspect of the present invention comprises a semiconductor laser chip, and a package sealing the semiconductor laser chip, wherein the package has a base portion mounted with the semiconductor laser chip, a sealing member and a window member through which light emitted from the semiconductor laser chip penetrates an outside thereof, the semiconductor laser chip is sealed with the base portion, the sealing member and the window member, and at least two of the base portion, the sealing member and the window member are bonded to each other through a sealant made of an ethylene-polyvinyl alcohol copolymer.

In the semiconductor laser apparatus according to the first aspect of the present invention, as hereinabove described, at least the two of the base portion, the sealing member and the window member are bonded to each other through the sealant made of the ethylene-polyvinyl alcohol copolymer. The ethylene-polyvinyl alcohol copolymer is a resin material with excellent gas barrier properties blocking outside air, and hence low molecular siloxane, volatile organic gas or the like existing outside the semiconductor laser apparatus (in the atmosphere) can be inhibited from penetrating into the sealant and entering the package. Further, the ethylene-polyvinyl alcohol copolymer hardly generates the aforementioned volatile component, and hence an adherent substance is inhibited from being formed on a laser emitting facet. Consequently, the semiconductor laser chip can be inhibited from deterioration. Further, the aforementioned ethylene-polyvinyl alcohol copolymer is a resin material enabling the members to be easily bonded to each other by thermocompression bonding, and hence the package can be sealed by bonding the base portion, the sealing member and the window member to each other without requiring a complicated manufacturing process. The inventor has found as a result of a deep study that the aforementioned ethylene-polyvinyl alcohol copolymer is employed as the material for the sealant in the present invention, handling of which is easy in the manufacturing process, having excellent gas barrier properties and hardly generating the volatile component forming the adherent substance on the laser emitting facet.

In the aforementioned semiconductor laser apparatus according to the first aspect, the sealing member and the window member are preferably bonded to each other through the sealant. According to this structure, a bonding state of the sealant can be confirmed through the window member having translucence when the sealing member and the window member are bonded to each other through the sealant. Thus, the sealing member and the window member can be reliably bonded to each other without formation of air bubbles in the sealant. Consequently, adhesiveness between the sealing member and the window member in a bonded portion can be increased. The window member is provided at a position separated from lead wires, and hence the window member is hardly influenced by heat generated in melting solder of the lead wires. Considering that the ethylene-polyvinyl alcohol copolymer has thermoplasticity, the use of the sealant in the present invention for bonding the window member hardly influenced by the heat is effective.

In the aforementioned semiconductor laser apparatus according to the first aspect, the sealing member is preferably made of metal. According to this structure, the sealant in the present invention has high adhesiveness to a metal surface, and hence adhesiveness between the sealing member and the window member in the bonded portion can be increased.

In the aforementioned semiconductor laser apparatus according to the first aspect, the sealing member is preferably made of glass. According to this structure, the sealant in the present invention has high adhesiveness to a glass surface, and hence adhesiveness between the sealing member and the window member in the bonded portion can be increased. In a case where a glass member is bonded to a metal member or the like, the sealing member and the window member can be reliably bonded to each other while confirming a bonding state of the sealant through the glass. Further, the sealant in the present invention is superior in flexibility, and hence the sealant can reduce a sudden impact applied to the bonded portion. Thus, the window member of glass can be inhibited from being easily broken.

In the aforementioned semiconductor laser apparatus according to the first aspect, the sealing member is preferably made of metal foil and bonded to the base portion through the sealant in a bonded region, and the sealant preferably extends to a surface of the sealing member other than the bonded region. According to this structure, the strength (rigidity) of the metal foil can be improved, and hence the sealing member having a prescribed magnitude of rigidity can be easily made even when the low-cost metal foil is employed. Further, unnecessary deformation in the manufacturing process can be prevented by increasing the rigidity, and handling in the manufacturing process becomes easier.

In the aforementioned structure having the sealing member made of the metal foil, the base portion preferably has an opening which opens from an upper surface to a front surface, the sealing member is preferably made of the metal foil having a side cross section bent in a substantially L-shaped manner from the upper surface to the front surface, and the sealant is preferably provided on a substantially entire surface of the sealing member facing sealed space of the package. According to this structure, the strength (rigidity) of the sealing member can be easily improved by the sealant provided along the surface of the sealing member facing the sealed space even when the metal foil is bent in a substantially L-shaped manner thereby forming the sealing member.

In the aforementioned semiconductor laser apparatus according to the first aspect, a bonded region of at least two of the base portion, the sealing member and the window member is preferably filled up with the sealant not to generate a hole penetrating from an inside of the sealed space to an outside thereof. According to this structure, the sealed space in the package can be reliably isolated from the outside of the package by the sealant with no hole penetrating from the inside of the sealed space to the outside thereof. Thus, the semiconductor laser chip can be reliably inhibited from deterioration.

In the aforementioned structure in which the bonded region is filled up with the sealant not to generate the hole penetrating from the inside of the sealed space to the outside thereof, the sealant preferably has a portion protruding from the bonded region into sealed space of the package, and a thickness of the protruding portion is preferably larger than a thickness of the sealant in the bonded region. According to this structure, low molecular siloxane, volatile organic gas or the like existing outside the semiconductor laser apparatus (in the atmosphere) can be effectively inhibited from penetrating into not only a portion of the sealant in the bonded region of at least the two of the base portion, the sealing member and the window member but also a portion of the sealant having a larger thickness than this bonded region and entering the package.

In this case, the portion of the sealant protruding into the sealed space preferably covers a surface of the base portion in the vicinity of the bonded region. According to this structure, an area of contact between the sealant and the base portion can be increased, and hence airtightness in the package can be further improved.

In the aforementioned structure having the sealing member and the window member bonded to each other through the sealant, the window member is preferably bonded onto a surface of the sealing member in sealed space of the package or a surface of the sealing member in an outside of the package opposite to the sealed space through the sealant. According to this structure, the window member can be mounted on both surfaces of the sealing member inside or outside the sealed space, and hence the degree of freedom in design of the semiconductor laser apparatus can be improved.

In the aforementioned semiconductor laser apparatus according to the first aspect, a side surface of the sealant is preferably covered with resin made of a material having smaller water vapor permeability than the sealant. According to this structure, the aforementioned resin having small water vapor permeability can reliably inhibit moisture or the like existing outside (in the atmosphere) from entering the package through the sealant from the bonded portion of the sealing member and the window member.

In the aforementioned semiconductor laser apparatus according to the first aspect, the sealing member is preferably in the form of a cylinder having a bottom portion. According to this structure, the package can be sealed in a state where the semiconductor laser chip is circumferentially surrounded by an inner surface of the sealing member extending in a longitudinal direction (an extensional direction of a cylindrical shape).

In the aforementioned semiconductor laser apparatus according to the first aspect, the base portion is preferably made of a metal plate and includes a first lead frame, the base portion preferably has a recess portion in the metal plate other than the first lead frame, and the semiconductor laser chip is preferably mounted on an inner bottom surface of the recess portion. According to this structure, a side surface of the base portion can be provided without employing resin unlike a conventional semiconductor laser apparatus, and hence the package is not filled with volatile organic gas or the like. Thus, the semiconductor laser chip can be reliably inhibited from deterioration. Further, the base portion and the first lead frame can be integrally formed, and hence the semiconductor laser apparatus can be easily manufactured with a reduced number of components.

In the aforementioned structure having the base portion including the first lead frame, the first lead frame preferably conducts with the inner bottom surface, and the semiconductor laser apparatus preferably further comprises a second lead frame passing through a posterior surface of the recess portion backward beyond the semiconductor laser chip with respect to a laser beam-emitting direction and insulated from the inner bottom surface by an insulating member, wherein the sealant is provided in the vicinity of at least a portion of the second lead frame mounted on the insulating member in sealed space of the package. According to this structure, sealability in the package can be maintained by the sealant provided inside the package even if the second lead frame passing through the posterior surface of the recess portion is provided. When the insulating member is made of resin, volatile organic gas generated by the resin member can be inhibited from penetrating into the sealant and entering the package.

In the aforementioned semiconductor laser apparatus according to the first aspect, a thickness of the sealant is preferably at least 5 μm and not more than 50 μm. According to this structure, the height (thickness) of the overall package can be rendered lower (thinner) without reducing sealability (airtightness) of the package. Further, an amount of the employed sealant can be reduced, and hence an amount of the sealant protruding to portions other than a bonded portion of the base portion and sealing member after bonding can be reduced, for example.

In the aforementioned semiconductor laser apparatus according to the first aspect, the semiconductor laser chip is preferably a nitride-based semiconductor laser chip. In the nitride-based semiconductor laser chip having a short lasing wavelength and requiring a higher output power, an adherent substance is easily formed on a laser emitting facet of the semiconductor laser chip, and hence the use of the aforementioned “sealant” in the present invention is highly effective in that the nitride-based semiconductor laser chip is inhibited from deterioration.

A method of manufacturing a semiconductor laser apparatus according to a second aspect of the present invention comprises steps of mounting a semiconductor laser chip on a base portion, and bonding at least two of the base portion, a sealing member and a window member to each other through a sealant made of an ethylene-polyvinyl alcohol copolymer by thermocompression bonding so as to seal the semiconductor laser chip.

As hereinabove described, the method of manufacturing a semiconductor laser apparatus according to the second aspect of the present invention comprises the step of bonding at least the two of the base portion, the sealing member and the window member to each other through the sealant made of the ethylene-polyvinyl alcohol copolymer by thermocompression bonding. In the present invention, a material, handling of which is easy in a manufacturing process, is employed as the sealant, and hence the package can be sealed by bonding the base portion, the sealing member and the window member to each other without requiring a complicated manufacturing process. Further, the ethylene-polyvinyl alcohol copolymer is employed as the sealant, and hence the semiconductor laser apparatus having the semiconductor laser chip inhibited from deterioration can be obtained.

In the aforementioned method of manufacturing a semiconductor laser apparatus according to the second aspect of the present invention, the step of bonding preferably includes a step of press-bonding the sealing member and at least one of the base portion and the window member to each other through the sealant after the melted sealant is applied to the sealing member. According to this structure, the melted sealant can be easily applied to a bonded region having a complicated shape, and hence at least the two of the base portion, the sealing member and the window member can be easily bonded to each other through the sealant.

In the aforementioned method of manufacturing a semiconductor laser apparatus according to the second aspect, the step of bonding preferably includes a step of press-bonding the sealing member and at least one of the base portion and the window member to each other in a state where the sealant formed in the form of a thin film is sandwiched therebetween. According to this structure, sealability (airtightness) similar to that in a case where the melted sealant is applied can be obtained even when use of the sealant is reduced, as compared with a case where the melted sealant is applied, and hence the height (thickness) of the overall package can be rendered lower (thinner) without reducing sealability (airtightness) of the package.

An optical apparatus according to a third aspect of the present invention comprises a semiconductor laser apparatus including a semiconductor laser chip and a package sealing the semiconductor laser chip, and an optical system controlling a beam emitted from the semiconductor laser apparatus, wherein the package has a base portion mounted with the semiconductor laser chip, a sealing member and a window member through which light emitted from the semiconductor laser chip penetrates an outside thereof, the semiconductor laser chip is sealed with the base portion, the sealing member and the window member, and at least two of the base portion, the sealing member and the window member are bonded to each other through a sealant made of an ethylene-polyvinyl alcohol copolymer.

In the optical apparatus according to the third aspect of the present invention, the semiconductor laser apparatus is formed as hereinabove described, and hence the optical apparatus loaded with the semiconductor laser apparatus in which the package is sealed without requiring a complicated manufacturing process and the semiconductor laser chip is inhibited from deterioration can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view of a semiconductor laser apparatus according to a first embodiment of the present invention in which a base portion and a sealing member are separated from each other;

FIG. 2 is a longitudinal sectional view taken along the center line of the semiconductor laser apparatus according to the first embodiment of the present invention in a width direction;

FIGS. 3 and 4 are top plan views for illustrating a manufacturing process of the semiconductor laser apparatus according to the first embodiment of the present invention;

FIGS. 5 to 7 are perspective views for illustrating the manufacturing process of the semiconductor laser apparatus according to the first embodiment of the present invention;

FIG. 8 is a longitudinal sectional view taken along the center line of a semiconductor laser apparatus according to a modification of the first embodiment of the present invention in a width direction;

FIG. 9 is an exploded perspective view of a semiconductor laser apparatus according to a second embodiment of the present invention in which a base portion and a sealing member are separated from each other;

FIG. 10 is a longitudinal sectional view taken along the center line of the semiconductor laser apparatus according to the second embodiment of the present invention in a width direction;

FIG. 11 is an exploded perspective view of a semiconductor laser apparatus according to a third embodiment of the present invention in which a base portion and a sealing member are separated from each other;

FIG. 12 is a longitudinal sectional view taken along the center line of the semiconductor laser apparatus according to the third embodiment of the present invention in a width direction;

FIGS. 13 and 14 are perspective views for illustrating a manufacturing process of the semiconductor laser apparatus according to the third embodiment of the present invention;

FIG. 15 is an exploded perspective view of a semiconductor laser apparatus according to a modification of the third embodiment of the present invention in which a base portion and a sealing member are separated from each other;

FIG. 16 is a longitudinal sectional view taken along the center line of the semiconductor laser apparatus according to the modification of the third embodiment of the present invention in a width direction;

FIG. 17 is an exploded perspective view of a semiconductor laser apparatus according to a fourth embodiment of the present invention in which a base portion and a cap portion of are separated from each other;

FIG. 18 is a longitudinal sectional view taken along the center line of the semiconductor laser apparatus according to the fourth embodiment of the present invention in a width direction;

FIG. 19 is a longitudinal sectional view taken along the center line of a semiconductor laser apparatus according to a modification of the fourth embodiment of the present invention in a width direction;

FIG. 20 is a longitudinal sectional view taken along the center line of a semiconductor laser apparatus according to a fifth embodiment of the present invention in a width direction;

FIGS. 21 and 22 are sectional views for illustrating a manufacturing process of a cap portion of the semiconductor laser apparatus according to the fifth embodiment of the present invention;

FIG. 23 is an exploded perspective view of a semiconductor laser apparatus according to a sixth embodiment of the present invention in which a cap portion and a base portion of are separated from each other;

FIG. 24 is a longitudinal sectional view taken along the center line of the semiconductor laser apparatus according to the sixth embodiment of the present invention in a width direction;

FIG. 25 is a longitudinal sectional view showing a structure of a semiconductor laser apparatus according to a seventh embodiment of the present invention;

FIG. 26 is a top plan view showing a structure of the semiconductor laser apparatus according to the seventh embodiment of the present invention;

FIGS. 27 to 29 are sectional views for illustrating a manufacturing process of the semiconductor laser apparatus according to the seventh embodiment of the present invention;

FIG. 30 is a top plan view of a three-wavelength semiconductor laser apparatus according to an eighth embodiment of the present invention, from which a sealing member is removed;

FIG. 31 is a schematic diagram showing a structure of an optical pickup comprising the three-wavelength semiconductor laser apparatus according to the eighth embodiment of the present invention;

FIG. 32 is a perspective view showing a state of bonding a sealing member to a base portion through a film sealant in a semiconductor laser apparatus according to a modification of the present invention;

FIG. 33 is a longitudinal sectional view taken along the center line of the semiconductor laser apparatus shown in FIG. 32 in a width direction.

### DESCRIPTION OF THE PREFERRED EMBODIMENTS

Embodiments of the present invention are hereinafter described with reference to the drawings.

### First Embodiment

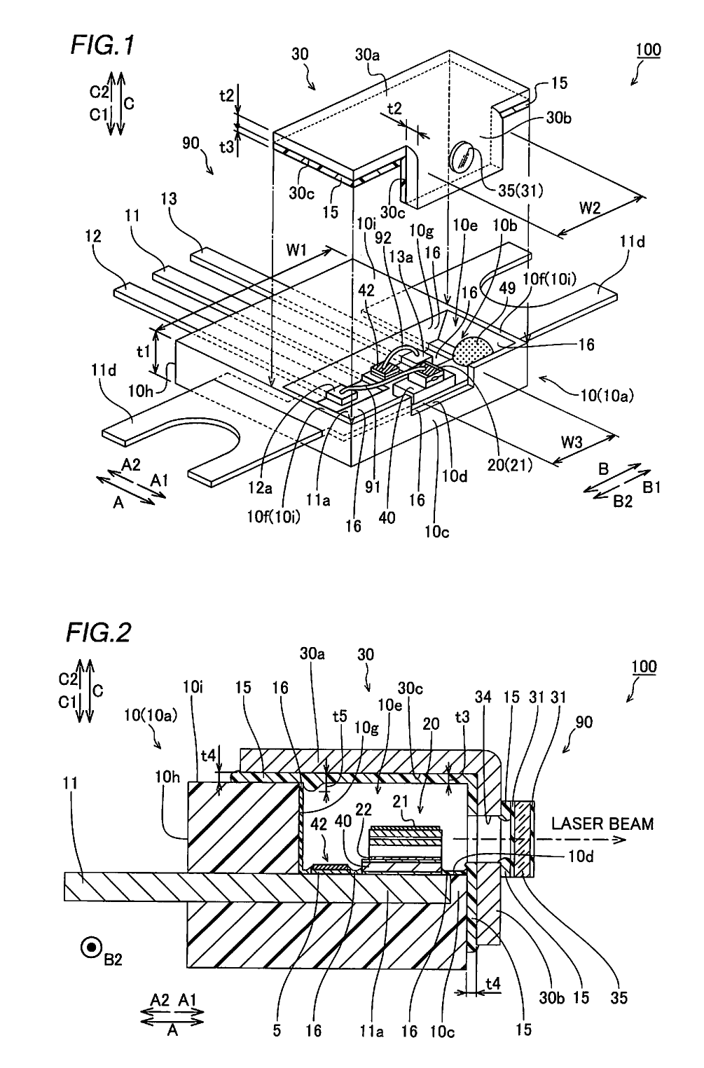

A structure of a semiconductor laser apparatus 100 according to a first embodiment of the present invention is now described with reference to FIGS. 1 and 2.

The semiconductor laser apparatus 100 according to the first embodiment of the present invention comprises a blue-violet semiconductor laser chip 20 having a lasing wavelength of about 405 nm and a package 90 sealing the blue-violet semiconductor laser chip 20. The package 90 has a base portion 10 mounted with the blue-violet semiconductor laser chip 20 and a sealing member 30 mounted on the base portion 10, covering the blue-violet semiconductor laser chip 20 from two directions, that is, from upper (a C2 side) and front (an A1 side) sides. The blue-violet semiconductor laser chip 20 is an example of the “semiconductor laser chip” in the present invention.

The base portion 10 has a tabular base body 10a with a thickness t1 (in a direction C) made of polyamide resin, as shown in FIG. 1. A recess portion 10b recessed by a depth about half the thickness t1 downward (to a C1 side) is formed in about a front half region of the tabular base body 10a. A front wall portion 10c of the base body 10a on the front side is provided with a substantially rectangular opening 10d having a width W3 on the central portion in a width direction (direction B). Therefore, the recess portion 10b is arranged with a substantially rectangular opening 10e, which opens in an upper surface 10i, and the opening 10d, which opens on the front side. The recess portion 10b is constituted by the front wall portion 10c, a pair of side wall portions 10f extending substantially parallel to each other backward (to an A2 side) from both side ends of the front wall portion 10c, an inner wall portion 10g connecting back ends (on the A2 side) of the side wall portions 10f and a bottom surface connecting the front wall portion 10c, the pair of side wall portions 10f and the inner wall portion 10g on the lower portion.

In the base portion 10, lead frames 11, 12 and 13 made of metal are so arranged as to pass through the base body 10a from the front side to the back side in a state of being isolated from each other. In plan view, the lead frame 11 passes through a substantially central portion of the base body 10a in the direction B while the lead frames 12 and 13 are arranged on the outer sides (a B2 side and a B1 side) of the lead frame 11 in the width direction. Back end regions of the lead frames 11, 12 and 13, extending backward are exposed from a back wall portion 10h of the base body 10a at the back.

Front end regions 11a, 12a and 13a of the lead frames 11, 12 and 13 at the front are exposed from the inner wall portion 10g of the base body 10a, and the front end regions 11a to 13a are arranged on the bottom surface of the recess portion 10b. The front end region 11a of the lead frame 11 widens in the direction B on the bottom surface of the recess portion 10b.

The lead frame 11 is integrally formed with a pair of heat radiation portions 11d connected to the front end region 11a. The pair of heat radiation portions 11d are arranged substantially symmetrically about the lead frame 11 on both sides in the direction B. The heat radiation portions 11d extend from the front end region 11a and pass through side surfaces of the base body 10a in directions B1 and B2 to be exposed. Therefore, heat generated by the operating blue-violet semiconductor laser chip 20 is transferred to a submount 40 and the heat radiation portions 11d on both sides to be radiated to the outside of the semiconductor laser apparatus 100.

The sealing member 30 is made of aluminum foil. The sealing member 30 has a ceiling surface portion 30a with a thickness t2 of about 50 μm and a width W1 (in the direction B) and a front surface portion 30b with a thickness t2 and a width W2 (W2≦W1) bent at an end of the ceiling surface portion 30a on one side (the A1 side) and extending downward, as shown in FIG. 1. The ceiling surface portion 30a and the front surface portion 30b are formed in a state of being substantially orthogonal to each other, whereby a side cross section of the sealing member 30 in a direction A is substantially L-shaped. The width W2 of the front surface portion 30b is larger than an opening length W3 of the opening 10d in the direction B (W2>W3).

As shown in FIG. 2, a sealant 15 with a thickness t3 of about 0.2 mm is applied to a substantially entire region on a back surface (inner surface 30c) of the sealing member 30. Eval (registered trademark, Eval F104B manufactured by Kuraray Co., Ltd.) which is EVOH resin is employed as the sealant 15. The EVOH resin is a material having excellent gas barrier properties and mainly employed in a food wrapper and so on as a multilayered film.

A hole 34 (window portion) penetrating through the sealing member 30 in a thickness direction is provided in a substantially central portion of the front surface portion 30b. A light transmission portion 35 having translucence, made of borosilicate glass with a thickness of about 0.25 mm is provided to cover the hole 34 from the outside (A1 side) of the front surface portion 30b. At this time, the light transmission portion 35 is bonded onto the front surface portion 30b through the sealant 15 with a thickness of about 0.1 mm applied around the hole 34. Therefore, the hole 34 is completely closed by the light transmission portion 35 mounted through the sealant 15. Dielectric films 31 of Al₂O₃ each serving as an antireflection layer are formed on surfaces of the light transmission portion 35 on the A1 and A2 sides. The light transmission portion 35 is an example of the “window member” in the present invention.

In this state, the sealing member 30 and the base portion 10 are bonded to each other through the sealant 15. In other words, the sealing member 30 is mounted on the base portion 10 through the sealant 15 in the periphery (a region near the inner wall portion 10g and respective upper surfaces of the pair of side wall portions 10f and the front wall portion 10c) of the opening 10e in the upper surface 10i and the periphery of the opening 10d in the front surface (an outer surface (on the A1 side) of the front wall portion 10c). A bonded region through the aforementioned sealant 15 is annularly formed. Thus, the openings 10d and 10e are completely closed by the sealing member 30, and the blue-violet semiconductor laser chip 20 is sealed with the package 90. Therefore, in the semiconductor laser apparatus 100, an adherent substance or the like caused by a volatile component is not generated or hardly generated on a light-emitting surface in the package 90. As shown in FIG. 2, the sealing member 30 is bonded to the base portion 10 by prescribed pressing force, and hence a thickness t4 of the sealant 15 in a bonded region of the inner surface 30c of the ceiling surface portion 30a and the upper surface 10i of the base body 10a is smaller than the thickness t3 of the sealant 15 in a region other than the bonded region. For example, the sealant 15 after bonding may have a thickness t5 (t5>t4) in a portion slightly inward beyond the bonded region (thickness t4) (inside the package 90) and protrude in the form of a fillet. Such a protruding shape may be formed along the inner and outer sides of the bonded region of the sealing member 30 and the base portion 10.

The blue-violet semiconductor laser chip 20 is mounted on a substantially central portion of an upper surface of the front end region 11a of the lead frame 11 through the submount 40 having conductivity. The blue-violet semiconductor laser chip 20 has a thickness (height (direction C)) of about 100 μm.

The blue-violet semiconductor laser chip 20 is mounted in a junction-up system such that the light-emitting surface faces forward. In a pair of cavity facets formed on the blue-violet semiconductor laser chip 20, that emitting a laser beam having relatively large light intensity serves as the light-emitting surface and that having relatively small light intensity serves as a light-reflecting surface. The blue-violet semiconductor laser chip 20 emits the laser beam in a direction A1. A dielectric multilayer film (not shown) made of an AlN film, an Al₂O₃ film or the like is formed on the light-emitting surface and the light-reflecting surface of the blue-violet semiconductor laser chip 20 by facet coating treatment in a manufacturing process.

A first end of a metal wire 91 made of Au or the like is bonded to a p-side electrode 21 formed on an upper surface of the blue-violet semiconductor laser chip 20, and a second end of the metal wire 91 is connected to the front end region 12a. An n-side electrode 22 formed on a lower surface of the blue-violet semiconductor laser chip 20 is electrically connected to the front end region 11a through the submount 40.

A photodiode (PD) 42 employed to monitor an intensity of a laser beam is arranged on a side of the light-reflecting surface of the blue-violet semiconductor laser chip 20 in a back portion of the submount 40 such that a photoreceiving surface faces upward. A lower surface (n-type region) of the tabular PD 42 is electrically connected to the front end region 11a through a conductive adhesive layer 5 made of Ag paste or the like. A first end of a metal wire 92 made of Au or the like is bonded to an upper surface (p-type region) of the PD 42, and a second end of the metal wire 92 is connected to the front end region 13a.

As shown in FIGS. 1 and 2, a covering agent 16 made of EVOH resin is applied with a prescribed thickness onto a surface of each member located in sealed space of the package 90. Specifically, the covering agent 16 continuously covers an inner surface (inner surfaces of the front wall portion 10c, the pair of side wall portions 10f and the inner wall portion 10g and a bottom surface of the recess portion 10b) of the recess portion 10b, a surface of the front end region 11a other than portions onto which the submount 40 and the PD 42 are bonded and surfaces of the front end regions 12a and 13a. At this time, a surface of the conductive adhesive layer 5 protruding from a lower portion of the PD 42 is also covered with the covering agent 16. Therefore, surfaces of the base body 10a of resin and the lead frames 11 to 13 located in the sealed space of the package 90 are completely covered with the covering agent 16.

As shown in FIG. 1, a gas absorbent 49 made of silica gel is provided on the front end region 11a on a side (B1 side) of the submount 40 in the package 90 through the covering agent 16. The gas absorbent 49 is formed substantially in the form of a hemisphere having a bottom surface underneath and fixed such that a top of a spherical surface comes into contact with the sealant 15 on the back surface (inner surface 30c) of the sealing member 30. The semiconductor laser apparatus 100 is constituted in the aforementioned manner.

A manufacturing process of the semiconductor laser apparatus 100 according to the first embodiment is now described with reference to FIGS. 1 to 7.

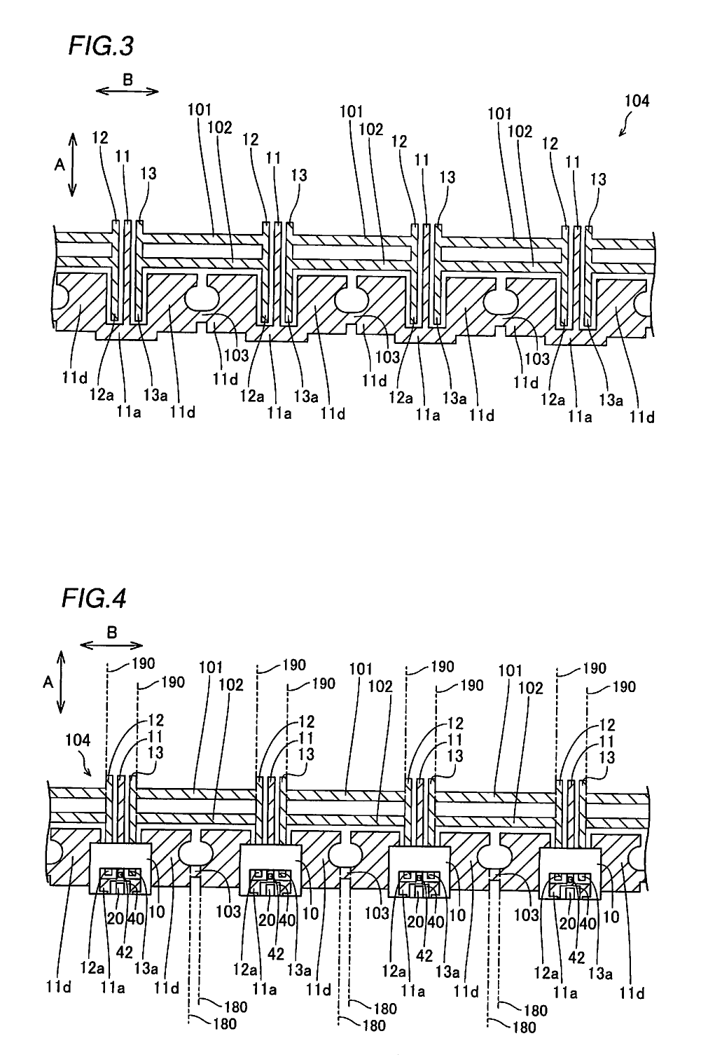

As shown in FIG. 3, a metal plate made of a strip-shaped thin plate of iron, copper or the like is etched, thereby forming a lead frame 104 in which the lead frame 11 having the heat radiation portions 11d formed integrally with the front end region 11a and the lead frames 12 and 13 arranged on both sides of the lead frame 11 are repeatedly patterned laterally. At this time, the lead frames 12 and 13 are patterned in a state of being coupled by coupling portions 101 and 102 extending laterally. The heat radiation portions 11d are patterned in a state of being coupled by a coupling portion 103 extending laterally.

Thereafter, the base portion 10 (see FIG. 1) having the base body 10a through which a set of the lead frames 11 to 13 passes and the recess portion 10b with the bottom surface on which the front end regions 11a to 13a of the respective terminals are exposed is molded into the lead frame 104 by a resin molding apparatus, as shown in FIG. 4. At this time, the base body 10a is so molded that the front end regions 11a to 13a of the lead frames 11 to 13 are arranged in the recess portion 10b.

The blue-violet semiconductor laser chip 20, the PD 42 and the submount 40 are prepared through prescribed manufacturing processes. Then, a chip of the blue-violet semiconductor laser chip 20 is bonded onto one surface (upper surface) of the submount 40 through a conductive adhesive layer (not shown). At this time, the n-side electrode 22 is bonded onto the upper surface of the submount 40.

Thereafter, the submount 40 is bonded onto the substantially central portion (in a lateral direction) of the upper surface of the front end region 11a through a conductive adhesive layer (not shown), as shown in FIG. 4. At this time, a lower surface of the submount 40 to which the blue-violet semiconductor laser chip 20 is not bonded is bonded onto the upper surface of the front end region 11a. Then, the lower surface of the PD 42 is bonded onto a region at the rear of the submount 40 and between the front end region 11a and the inner wall portion 10g through the conductive adhesive layer 5. At this time, the n-type region of the PD 42 is bonded to the lead frame 11.

Thereafter, the p-side electrode 21 and the front end region 12a are connected with each other through the metal wire 91, as shown in FIG. 1. The p-type region (upper surface) of the PD 42 and the front end region 13a are connected with each other through the metal wire 92.

Then, the covering agent 16 is applied to continuously cover the inner surface (the inner surfaces of the front wall portion 10c, the pair of side wall portions 10f and the inner wall portion 10g and the bottom surface of the recess portion 10b) of the recess portion 10b, the surface of the front end region 11a other than the portions onto which the submount 40 and the PD 42 are bonded and the surfaces of the front end regions 12a and 13a in a state where the base portion 10 is heated to about 230° C. Thus, the covering agent 16 is also applied to the vicinities of the ends of the metal wires 91 and 92 on sides of the lead frames.

After cooling the base portion 10, the lead frame 104 is cut along division lines 180 and 190, as shown in FIG. 4, thereby cutting and removing the coupling portions 101, 102 and 103. Thereafter, the gas absorbent 49 is placed on the front end region 11a on the side (B1 side) of the submount 40.

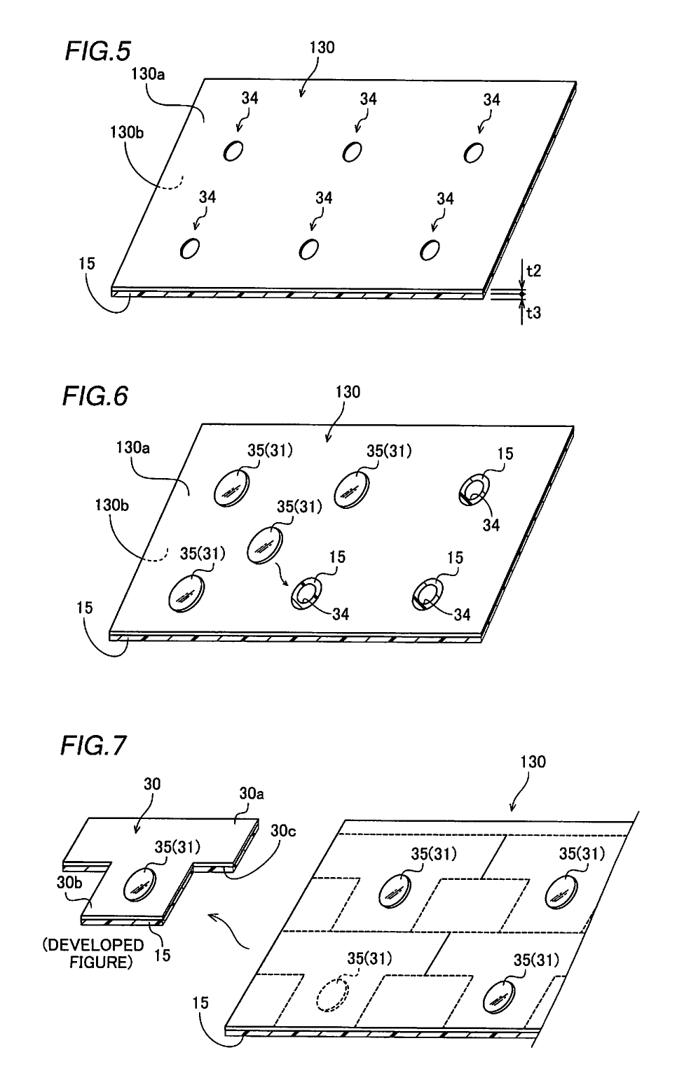

Meanwhile, as shown in FIG. 5, the sealant 15 is applied with a thickness of about 0.2 mm onto an entire back surface 130b in a state where a sheet-like aluminum foil 130 having a thickness t2 of about 0.17 μm is heated to about 220° C. Thereafter, a plurality of the holes 34 are formed in prescribed regions of the aluminum foil 130 at prescribed intervals. The aluminum foil 130 is an example of the “metal foil” in the present invention.

Thereafter, the sealant 15 is annularly applied to the periphery of the hole 34 on an upper surface 130a of the aluminum foil 130 heated to about 220° C., as shown in FIG. 6. In a state where the sealant 15 is melted by heat, the light transmission portion 35 formed in a substantially disc shape and formed with the dielectric films 31 is press-bonded to close the hole 34. Thereafter, the aluminum foil 130 is cooled thereby bonding the light transmission portion 35 onto the aluminum foil 130 through the sealant 15. The sealant 15 applied onto the back surface 130b is also hardened by cooling, and hence a prescribed magnitude of rigidity is produced in the plate-like sealing member 30. Then, the aluminum foil 130 is cut in a shape of the sealing member 30 developed on a plane surface, as shown in FIG. 7.

Thereafter, the unbent sealing member 30 is thermocompression bonded onto an upper surface of the base portion 10 in a state where the base portion 10 is heated to about 220° C., and the sealing member 30 is thermocompression bonded onto a front surface of the front wall portion 10c while bending the sealing member 30 along the front wall portion 10c such that the front surface portion 30b is perpendicular to the ceiling surface portion 30a. In the sealing member 30, the sealant 15 starts to melt by surrounding heat, and hence the aluminum foil 130 is rendered deformable. Then, the base portion 10 is cooled thereby mounting the sealing member 30 on the base portion 10. When mounting the sealing member 30, the melted sealant 15 on the front end region 11a and a back surface of the sealing member 30 comes into contact with the gas absorbent 49, and hence the gas absorbent 49 can be adhered to the sealant 15 on the front end region 11a and the back surface of the sealing member 30 after cooling. Thus, the sealing member 30 is formed in a shape shown in FIG. 2. The semiconductor laser apparatus 100 is formed in the aforementioned manner.

As hereinabove described, the base portion 10, the sealing member 30 and the light transmission portion 35 are bonded to each other through the sealant 15 made of the EVOH resin, and hence low molecular siloxane, volatile organic gas or the like existing outside the semiconductor laser apparatus 100 (in the atmosphere) can be inhibited from penetrating into the sealant 15 and entering the package 90. Further, the EVOH resin hardly generates the aforementioned volatile component, and hence the adherent substance is inhibited from being formed on a laser emitting facet. Consequently, the blue-violet semiconductor laser chip 20 can be inhibited from deterioration.

The aforementioned EVOH resin has a property of melting by heat (about 220° C.), and hence the EVOH resin can be easily applied to a bonded portion of the sealing member 30 and the light transmission portion 35 and a bonded portion of the sealing member 30 and the base portion 10 (base body 10a). The aforementioned members can be easily bonded to each other by hardening of the sealant 15 following removal of heat (cooling). Thus, the package 90 can be sealed by bonding the base portion 10, the sealing member 30 and the light transmission portion 35 to each other without requiring a complicated manufacturing process.

Surfaces of the resin base body 10a, the outer periphery of the PD 42, the metal lead frames 11 to 13 and so on located in the sealed space (closed space surrounded by the base portion 10 and the sealing member 30) of the package 90 are completely covered with the covering agent 16. Thus, the covering agent 16 can block volatile organic gas from penetrating into the sealed space of the package 90 also when the volatile organic gas is generated from a material (polyamide resin) of the base portion 10, the conductive adhesive layer 5 (Ag paste) or the like. Further, even when low molecular siloxane, volatile organic gas or the like existing outside the semiconductor laser apparatus 100 (in the atmosphere) penetrates into the components of the package 90, the covering agent 16 can inhibit the low molecular siloxane, volatile organic gas or the like from entering the package 90. Further, the EVOH resin hardly generates the aforementioned volatile component, and hence the semiconductor laser chip 20 in the package 90 is not exposed to the organic gas or the like. Consequently, the adherent substance can be inhibited from being formed on the laser emitting facet, and hence the semiconductor laser chip 20 can be more effectively inhibited from deterioration.

The base portion 10 is made of polyamide resin whereby the manufacturing process can be simplified as compared with a case where the package is made of a conventional metal material. The semiconductor laser apparatus 100 can be inexpensively manufactured due to a reduced material cost and the simplified manufacturing process.

In order to confirm usefulness of employing the EVOH resin as the sealant 15 and the covering agent 16, the following experiment was performed. First, the blue-violet semiconductor laser chip 20 was mounted on a metal stem (base portion) having a diameter (outer diameter) of 9 mm, and in a state where a pellet of EVOH resin cut to weigh about 5 mg was put on an inner surface of a metal cap portion (with a glass window), the stem was sealed with the cap portion. Then, an operation test was performed by emitting a laser beam adjusted to 10 mW output power by Automatic Power Control (APC) from the blue-violet semiconductor laser chip 20 for 250 hours under a condition of 70° C. Consequently, an operating current of a semiconductor laser apparatus did not remarkably change even after 250 hours. As a comparative example, an operation test was performed in a semiconductor laser apparatus having the semiconductor laser chip sealed without putting the EVOH resin on the inner surface of the cap portion. The operating current was not remarkably different from that in the comparative example after 250 hours. From these results, it has been confirmed that the EVOH resin hardly generates organic gas or the like, and usefulness of employing the EVOH resin as the sealant 15 and the covering agent 16 has been confirmed.

The sealing member 30 is mounted on the base portion 10 to cover the semiconductor laser chip, and the sealing member 30 and the light transmission portion 35 are bonded to each other through the sealant 15. Thus, a bonding state of the sealant 15 can be confirmed through the light transmission portion 35 having translucence when the sealing member 30 and the light transmission portion 35 are bonded to each other through the sealant 15, and hence the sealing member 30 and the light transmission portion 35 can be reliably bonded to each other without formation of air bubbles in the sealant 15. Consequently, adhesiveness between the sealing member 30 and the light transmission portion 35 in the bonded portion can be increased. The light transmission portion 35 is provided at a position separated from the metal wires 91 and 92, and hence the light transmission portion 35 is hardly influenced by heat generated in melting solder of the metal wires 91 and 92. Considering that the EVOH resin has thermoplasticity, the use of the sealant 15 in the present invention for bonding the light transmission portion 35 insusceptible to heat is effective.

The sealant 15 made of the EVOH resin is formed on the entire inner surface 30c of the sealing member 30 having a side cross section bent in a substantially L-shaped manner, and hence even the physical strength (rigidity) of the aluminum 130 in the form of a thin film normally insufficient for the component of the package 90 is increased by the sealant 15 provided on the entire inner surface 30c. Consequently, the sealing member 30 having a prescribed magnitude of rigidity can be easily made even when a low-cost metal foil is employed. Further, unnecessary deformation in the manufacturing process can be prevented by increasing the rigidity. Further, if the sealant 15 is previously formed on the sealing member 30, the package 90 can be sealed simply by pressing the sealing member 30 against the heated base portion 10 and cooling the same, and hence handling in the manufacturing process becomes easier.

The bonded region of the base portion 10 and the sealing member 30 and a bonded region of the sealing member 30 and the light transmission portion 35 are filled with up the sealant 15 not to generate a hole penetrating from the inside of the sealed space to the outside thereof. Thus, the sealed space in the package 90 can be reliably isolated from the outside of the package 90 by the sealant 15 with no hole penetrating from the inside of the sealed space to the outside thereof, and hence the blue-violet semiconductor laser chip 20 can be reliably inhibited from deterioration.

The sealant 15 protrudes from the bonded region of the base portion 10 and the sealing member 30 and the bonded region of the sealing member 30 and the light transmission portion 35 into the sealed space of the package 90, and the thickness t5 in a portion of the sealant 15 protruding into the sealed space is larger than the thickness t4 in a bonded region of the sealant 15. Thus, low molecular siloxane, volatile organic gas or the like existing outside the semiconductor laser apparatus 100 (in the atmosphere) can be effectively inhibited from penetrating into not only portions of the sealant 15 in the bonded region of the base portion 10 and the sealing member 30 and the bonded region of the sealing member 30 and the light transmission portion 35 but also portions having a larger thickness than these bonded regions and entering the package 90.

The portion of the sealant 15 protruding into the sealed space partially covers a surface (the front wall portion 10c and the inner wall portion 10g) of the base body 10a in the vicinity of the bonded region in the sealed space, and hence an area of contact between the sealant 15 and the base body 10a can be increased. Thus, airtightness in the package 90 can be further improved.

The light transmission portion 35 is bonded to the front surface portion 30b of the sealing member 30 outside the package 90 through the sealant 15. Thus, a surface (on a side of the sealed space in the package) of the sealing member 30 mounted on the front wall portion 10c can be rendered flat, and hence the sealing member 30 can be easily mounted on the concave base portion 10.

The gas absorbent 49 is provided in the package 90, whereby volatile organic gas generated by the base body 10a can be absorbed by the gas absorbent 49. Thus, a concentration of organic gas in the package 90 can be reduced. Consequently, the blue-violet semiconductor laser chip 20 can be more reliably inhibited from deterioration.

The blue-violet semiconductor laser chip 20 is sealed in the package 90. In a nitride-based semiconductor laser chip having a short lasing wavelength and requiring a higher output power, an adherent substance is easily formed on a laser emitting facet of the semiconductor laser chip, and hence the use of the sealant 15 is highly effective in that the blue-violet semiconductor laser chip 20 is inhibited from deterioration.

The sealant 15 melted by heat is annularly applied onto the upper surface 130a of the aluminum foil 130, and thereafter the light transmission portion 35 is thermocompression bonded to close the hole 34, and the aluminum foil 130 cut in a prescribed shape is thermocompression bonded to the base portion 10 thereby forming the sealing member 30. Thus, the melted sealant 15 can be easily applied to the bonded region of the base portion 10 having a complicated shape, and hence the base portion 10 and the sealing member 30 can be easily bonded to each other. Further, the light transmission portion 35 closing the hole 34 can be easily bonded to the sealing member 30.

### Modification of First Embodiment

A semiconductor laser apparatus 105 according to a modification of the first embodiment is now described. In this semiconductor laser apparatus 105, a sealing member 30 is made of aluminum foil with a thickness of about 50 μm. At this time, a sealant 15 is not applied onto an inner surface 30c of the sealing member 30 located in sealed space of a package 90, and a surface of the aluminum foil is exposed in the sealed space. On the other hand, the sealant 15 is applied with a prescribed thickness onto a peripheral region (a region near an inner wall portion 10g and respective upper surfaces of a pair of side wall portions 10f and a front wall portion 10c) of an opening 10e in an upper surface 10i of a base body 10a and a peripheral region of an opening 10d in the front surface (an outer surface (on an A1 side) of the front wall portion 10c) so as to surround the peripheries of the openings 10e and 10d shown in FIG. 1. In this state, the sealing member 30 is mounted on a base portion 10 by bringing the vicinity of an outer edge of the inner surface 30c of a ceiling surface portion 30a and a front surface portion 30b into close contact with the sealant 15. The sealant 15 is applied only onto a bonded region of the base body 10a, and hence the sealant 15 partially protrudes into the package 90 when the sealing member 30 is bonded to the base portion 10 by prescribed pressing force. The remaining structure of the semiconductor laser apparatus 105 according to the modification of the first embodiment is substantially similar to that of the semiconductor laser apparatus 100 according to the first embodiment and denoted by the same reference numerals in the figure.

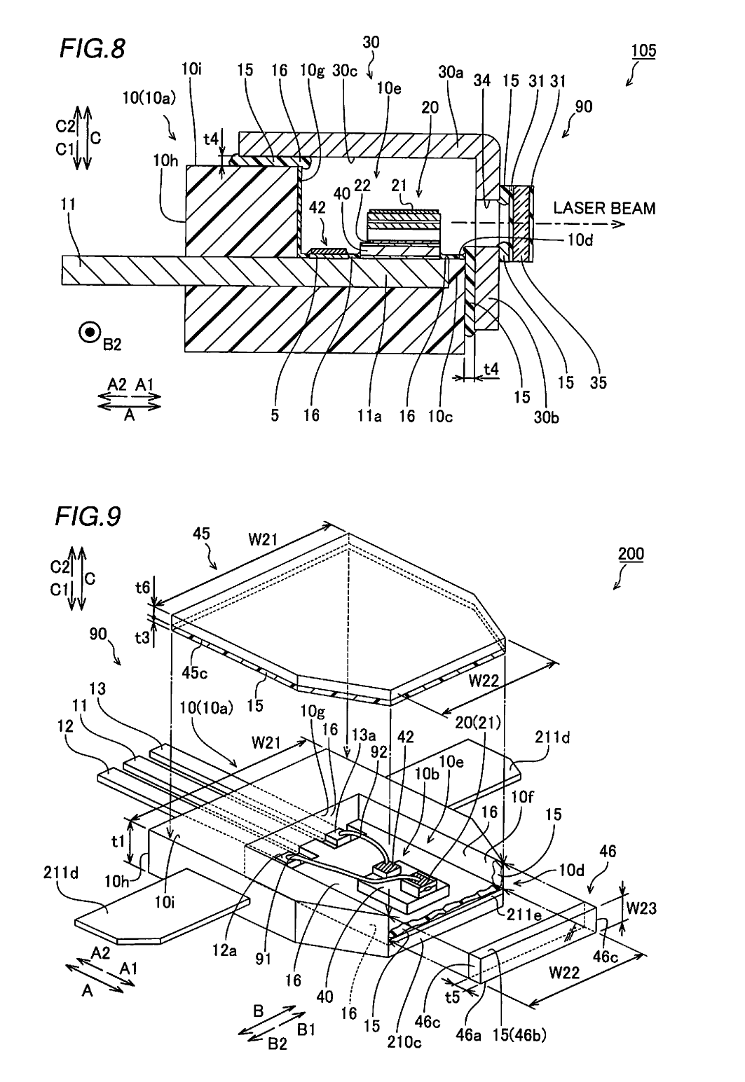

In a manufacturing process of the semiconductor laser apparatus 105, a light transmission portion 35 is bonded onto an aluminum foil 130 (see FIG. 5) having a lower surface 130b onto which the sealant 15 is not applied, similarly to the first embodiment. After the sealing member 30 similar to that of the first embodiment is prepared, the front surface portion 30b is bent in a direction perpendicular to the ceiling surface portion 30a such that the light transmission portion 35 is located outside. Thus, the sealing member 30 is previously formed in a shape shown in FIG. 8 before the same is thermocompression bonded onto the base portion 10, dissimilarly to the first embodiment.

Thereafter, the sealant 15 continuously covering the periphery (the region near the inner wall portion 10g and the respective upper surfaces of the pair of side wall portions 10f and the front wall portion 10c) of the opening 10e in the upper surface 10i and the periphery of the opening 10d in the front surface (the outer surface of the front wall portion 10c) is so applied as to surround the peripheries of the openings 10e and 10d of the base portion 10 in a state where the base portion 10 is heated to about 220° C. In a state where the sealant 15 is melted by heat, the sealing member 30 is thermocompression bonded onto the base portion 10. Thereafter, the base portion 10 is cooled, whereby the sealing member 30 is mounted on the base portion 10.

The remaining manufacturing process is substantially similar to that of the first embodiment. The effects of the modification of the first embodiment are similar to those of the first embodiment.

### Second Embodiment

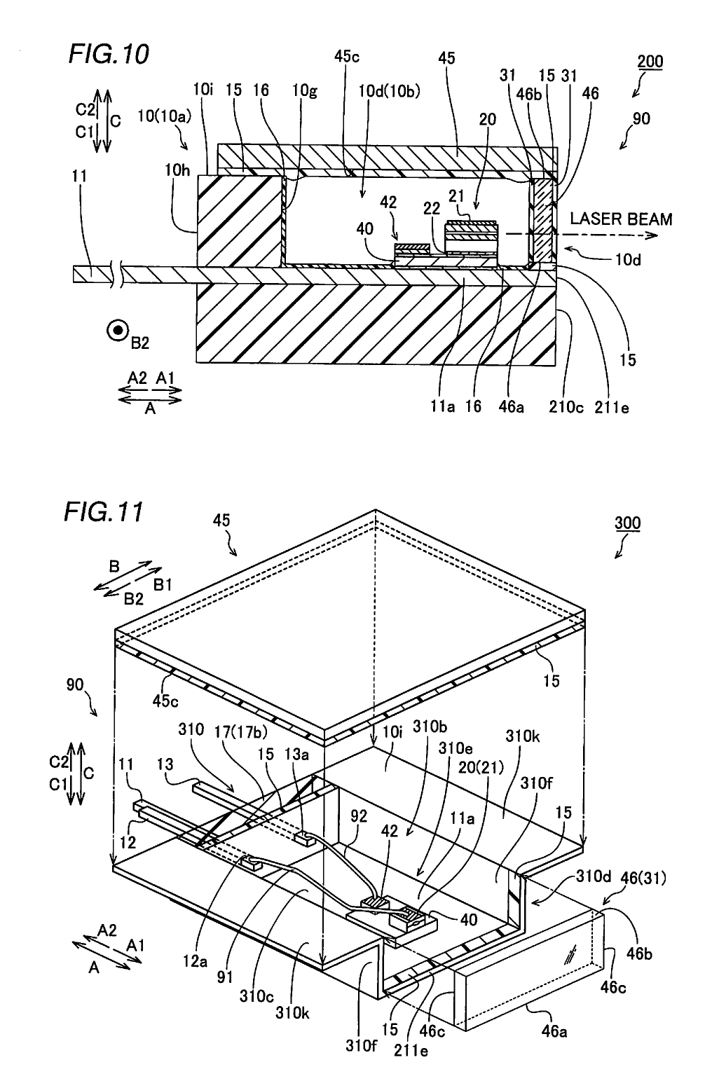

A semiconductor laser apparatus 200 according to a second embodiment of the present invention is now described. In this semiconductor laser apparatus 200, as shown in FIGS. 9 and 10, a package 90 has a base portion 10, and a sealing member 45 and a window member 46 both mounted on the base portion 10, covering a blue-violet semiconductor laser chip 20 from upper (a C2 side) and front (an A1 side) sides, respectively. While a gas absorbent 49 (see FIG. 1) is not provided in a recess portion 10b in the semiconductor laser apparatus 200, the gas absorbent 49 may be provided in the recess portion 10b.

A base body 10a has a tapered outer shape in which a width (in a direction B) is decreased toward a front end portion 210c from the back (direction A2) as viewed from a side of an upper surface 10i.

The sealing member 45 is made of Cu alloy foil such as nickel silver with a thickness t6 of about 15 μm. The sealing member 45 has a planar shape substantially identical to a planar shape of the base body 10a, and a width W21 at the back and a width W22 at the front. A sealant 15 having a thickness t3 of about 0.2 mm is applied onto a substantially entire region of a back surface 45c of the sealing member 45.

The window member 46 is made of a tabular glass plate of borosilicate glass (hard glass). The window member 46 has a thickness t5 (in a direction A) of about 0.25 mm, a width W22 (in the direction B) and a height W23 (in a direction C) substantially equal to a depth (t1/2) of the recess portion 10b and is mounted in an opening 10d. At this time, the sealant 15 continuously covering an inner surface of the opening 10d (an upper surface of a front end region 11a of a lead frame 11 in the opening 10d and respective inner surfaces of a pair of side wall portions 10f) is applied with a prescribed thickness between the window member 46 and the base body 10a. In this state, the window member 46 is mounted while bringing a lower surface 46a and both side surfaces 46c into close contact with the sealant 15. Dielectric films 31 are formed on surfaces (on A1 and A2 sides) of the window member 46.

Then, the sealing member 45 is mounted on the base portion 10 from an upper side of an opening 10e. In other words, the sealing member 45 is mounted on the base portion 10 through the sealant 15 in the upper surface 10i (a region near an inner wall portion 10g and respective upper surfaces of the pair of side wall portions 10f) of the base body 10a and an upper surface 46b of the window member 46.

A PD 42 is arranged on a side of a light-reflecting surface of the blue-violet semiconductor laser chip 20 in a back portion (on the A2 side) of a submount 40 such that a photoreceiving surface faces upward (in a direction C2). A lower surface (n-type region) of the PD 42 is electrically connected to the submount 40. The remaining structure of the semiconductor laser apparatus 200 is substantially similar to that of the semiconductor laser apparatus 100 according to the first embodiment and denoted by the same reference numerals in the figures.

In a manufacturing process of the semiconductor laser apparatus 200, a lead frame in which heat radiation portions 211d having a smaller length (in the direction A) than the heat radiation portions 11d are repeatedly patterned together with lead frames 11 to 13 is formed, and thereafter the base body 10a is molded by a resin molding apparatus. The base body 10a is so molded that the front end portion 210c is aligned on the same plane as a front end surface 211e of the front end region 11a of the lead frame 11.

Thereafter, the sealant 15 is applied onto the inner surface of the opening 10d (the upper surface of the front end region 11a in the opening 10d and the respective inner surfaces of the pair of side wall portions 10f) in a state where the base portion 10 is heated to about 220° C. In a state where the sealant 15 is melted by heat, the window member 46 is thermocompression bonded and mounted by being fitted into the opening 10d. Thus, the window member 46 is mounted on the base body 10a while bringing the lower surface 46a and the both side surfaces 46c into close contact with the upper surface of the front end region 11a and the inner surfaces of the side wall portions 10f through the sealant 15.

Thereafter, UV cleaning treatment or heating treatment at about 200° C. in vacuum is performed on the base portion 10. Thus, contaminations adhering to the recess portion 10b in the manufacturing process are removed, or fluid or a solvent included in polyamide resin is evaporated to be removed.

Thereafter, the submount 40 to which the blue-violet semiconductor laser chip 20 and the PD 42 are bonded through a conductive adhesive layer (not shown) is bonded onto a substantially central portion (in a lateral direction) of the upper surface of the front end region 11a. At this time, a light-emitting surface of the blue-violet semiconductor laser chip 20 faces the window member 46, and the light-reflecting surface of the blue-violet semiconductor laser chip 20 and the PD 42 face the inner wall portion 10g.

Thereafter, a p-side electrode 21 of the blue-violet semiconductor laser chip 20 and a front end region 12a of the lead frame 12 are connected with each other through a metal wire 91. An upper surface of the PD 42 and a front end region 13a of the lead frame 13 are connected with each other through a metal wire 92.

The sealant 15 (EVOH resin) is applied with a thickness of about 0.2 mm onto the entire back surface 45c heated to about 220° C., and the nickel silver sheet is cut out to have the planar shape (see FIG. 9) substantially identical to the planar shape of the base body 10a after cooling, whereby the sealing member 45 is formed.

Thereafter, the sealing member 45 is thermocompression bonded onto the upper surface 10i and an upper surface 46c to cover the opening 10d in a state where the base portion 10 is heated to about 220° C. Thus, the sealing member 45 is mounted on the base body 10a while bringing the back surface 45c into close contact with the upper surface 10i and the upper surface 46b through the sealant 15. The remaining manufacturing process is substantially similar to that of the first embodiment.

According to the second embodiment, as hereinabove described, the opening 10d of the base body 10a is sealed with the window member 46 through the sealant 15, and the opening 10e of the base body 10a is sealed with the sealing member 45 through the sealant 15. The window member 46 and the sealing member 45 can be further strongly mounted on the base body 10a with no clearance by employing the sealant 15, and hence the package 90 can be reliably sealed. Thus, the blue-violet semiconductor laser chip 20 in the package 90 can be inhibited from deterioration.

Further, the openings 10d and 10e which open from the upper surface 10i to the front end portion 210c of the base body 10a are sealed with the window member 46 and the sealing member 45, respectively, and hence clearances are hardly generated in the boundaries of the upper surface 10i of the opening 10e and the front end portion 210c of the opening 10d. Thus, the package 90 can be reliably sealed, and hence the blue-violet semiconductor laser chip 20 in the package 90 can be reliably inhibited from deterioration.

### Third Embodiment

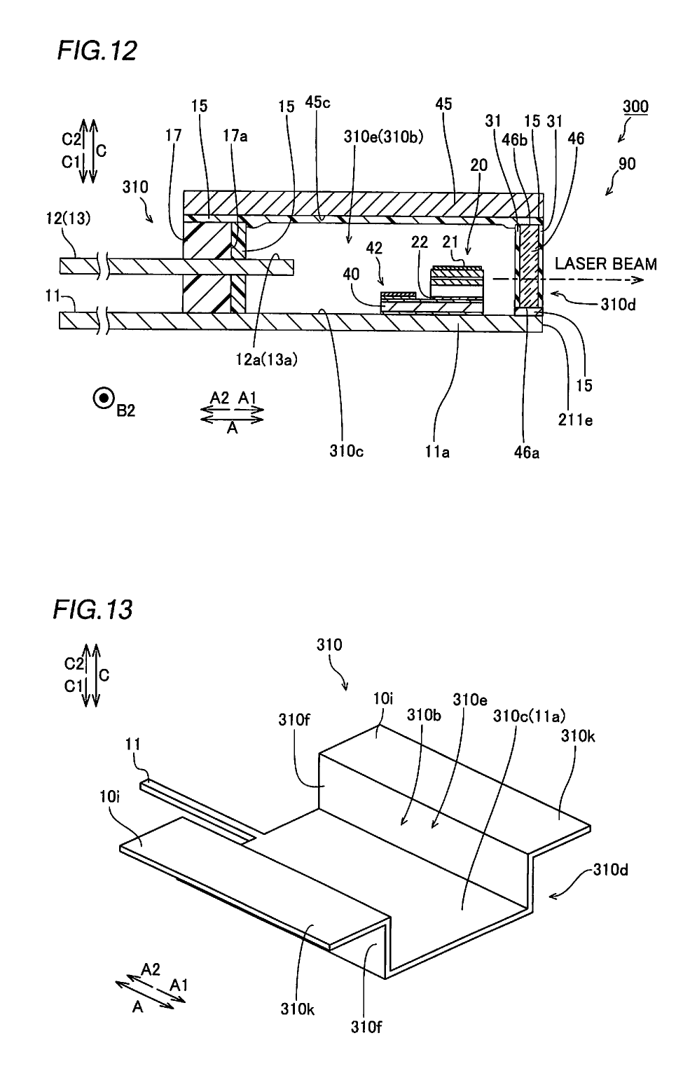

A semiconductor laser apparatus 300 according to a third embodiment of the present invention is now described. This semiconductor laser apparatus 300 comprises a base portion 310 made of metal in place of the base portion 10 made of resin in the semiconductor laser apparatus 200 according to the second embodiment, as shown in FIGS. 11 and 12. FIG. 12 includes a sectional view showing a mounting structure of a lead frame 12 (13) and the base portion 310 in a part of a longitudinal sectional view taken along the center line of the semiconductor laser apparatus 300 in a width direction (direction B).

A metal plate made of phosphor bronze with a thickness of about 0.4 mm is employed as the base portion 310. In the base portion 310, a front end region 11a of a lead frame 11 widening in a width direction (direction B) is bent along a length direction (direction A), and a groove-shaped recess portion 310b is formed. A submount 40 is fixed onto an inner bottom surface 310c of the recess portion 310b. A covering agent 16 is not applied onto an inner surface of the recess portion 310b of the base portion 310, and a metal surface thereof is exposed in sealed space of a package 90. The lead frame 11 is an example of the “first lead frame” in the present invention.

The recess portion 310b has an opening 310e, which opens in an upper surface 10i of the base portion 310, and an opening 310d, which opens at the front (on an A1 side). The base portion 310 is constituted by a pair of side wall portions 310f extending substantially parallel to each other backward from the opening 310d on both sides (B2 and B1 sides) of the inner bottom surface 310c of the recess portion 310b in the width direction and mounting portions 310k extending in the width direction (to the B1 and B2 sides) in respective upper end portions of the side wall portions 310f. A sealing member 17 made of epoxy resin is provided to close a substantially rectangular opening in a back portion of the base portion 310. A sealant 15 having a thickness of about 0.5 mm is applied onto an inner surface 17a of the sealing member 17 closer to the recess portion 310b (on the A1 side). The sealing member 17 is an example of the “insulating member” in the present invention.

As shown in FIG. 11, the lead frames 12 and 13 are so arranged as to pass through the sealant 15 and the sealing member 17 from the front side to the back side in a state of being isolated from each other by the sealing member 17. At this time, the lead frames 12 and 13 are held on a plane in a height direction (direction C) different from the lead frame 11 (front end region 11a). The lead frames 12 and 13 and the inner bottom surface 310c (lead frame 11) are isolated from each other by the sealing member 17. The lead frames 12 and 13 are an example of the “first lead frame” in the present invention.

A window member 46 is fixed through the sealant 15 applied in the opening 310d, similarly to the second embodiment. The sealing member 45 is mounted on upper surfaces of the mounting portions 310k of the base portion 310, an upper surface 46c of the window member 46 and an upper surface 17b of the sealing member 17.

The remaining structure of the semiconductor laser apparatus 300 is substantially similar to that of the semiconductor laser apparatus 200 according to the second embodiment and denoted by the same reference numerals in the figures.

In a manufacturing process of the semiconductor laser apparatus 300, a strip-shaped metal plate made of phosphor bronze is etched, thereby forming a lead frame in which the lead frame 11 is repeatedly patterned laterally, similarly to the first embodiment. At this time, the lead frames 12 and 13 and the heat radiation portions 11d are not patterned, unlike those in FIG. 3.

Thereafter, as shown in FIG. 13, the front end region 11a is cut vertically (in the direction A) on both sides in the width direction (direction B) at prescribed distances from the lead frame 11, whereby an unbent tabular lead frame is obtained. The front end region 11a is partially bent upward with respect to an upper surface of the lead frame by employing a pressing machine (not shown) or the like. Thus, the base portion 310 having the inner bottom surface 310c connected with the lead frame 11 on the same plane, the side wall portions 310f bent upward in both ends of the inner bottom surface 310c and the mounting portions 310k bent transversely (in the direction B) again from ends of the side wall portions 310k (on the B2 and B1 sides) is formed.

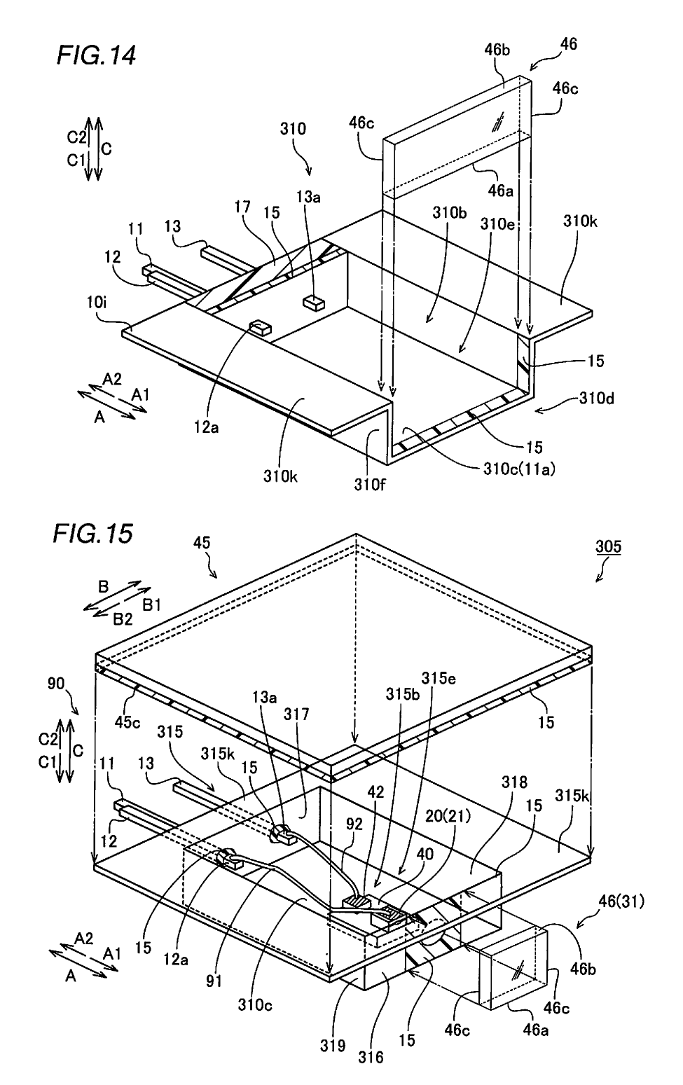

Thereafter, the opening of the recess portion 310b closer to the lead frame 11 (on an A2 side) is closed by the sealing member 17 made of epoxy resin with a resin molding apparatus (not shown), as shown in FIG. 14. At this time, the epoxy resin is hardened in a state where the lead frames 12 and 13 are so arranged as to pass through the sealing member 17 above the lead frame 11. Then, the sealant 15 is applied onto the inner surface 17a of the sealing member 17 in a state where the base portion 310 is heated to about 220° C.

Thereafter, the window member 46 is thermocompression bonded through the sealant 15 and mounted to close the opening 310d of the base portion 310, substantially similarly to the manufacturing process of the semiconductor laser apparatus 200. Then, the sealing member 45 is thermocompression bonded through the sealant 15 and mounted to close the opening 310e of the base portion 310. The remaining manufacturing process is substantially similar to that of the second embodiment.

According to the third embodiment, as hereinabove described, the base portion 310 is made of a metal plate, and hence volatile organic gas is not generated from the base portion 310. Thus, the package 90 is not filled with the volatile organic gas or the like, and hence the blue-violet semiconductor laser chip 20 can be reliably inhibited from deterioration.

The substantially rectangular opening in the back portion of the base portion 310 is closed by the sealing member 17 made of epoxy resin, and hence the sealing member 17 can also serve as a posterior surface of the base portion 310 (recess portion 310b). Thus, the package 90 sealing the blue-violet semiconductor laser chip 20 can be easily formed.

The sealant 15 is applied onto the inner surface 17a of the sealing member 17, and hence volatile organic gas generated by the sealing member 17 made of epoxy resin can be inhibited from penetrating into the sealant 15 and entering the package 90. Consequently, the blue-violet semiconductor laser chip 20 can be more reliably inhibited from deterioration. The remaining effects of the third embodiment are similar to those of the first embodiment.

### Modification of Third Embodiment

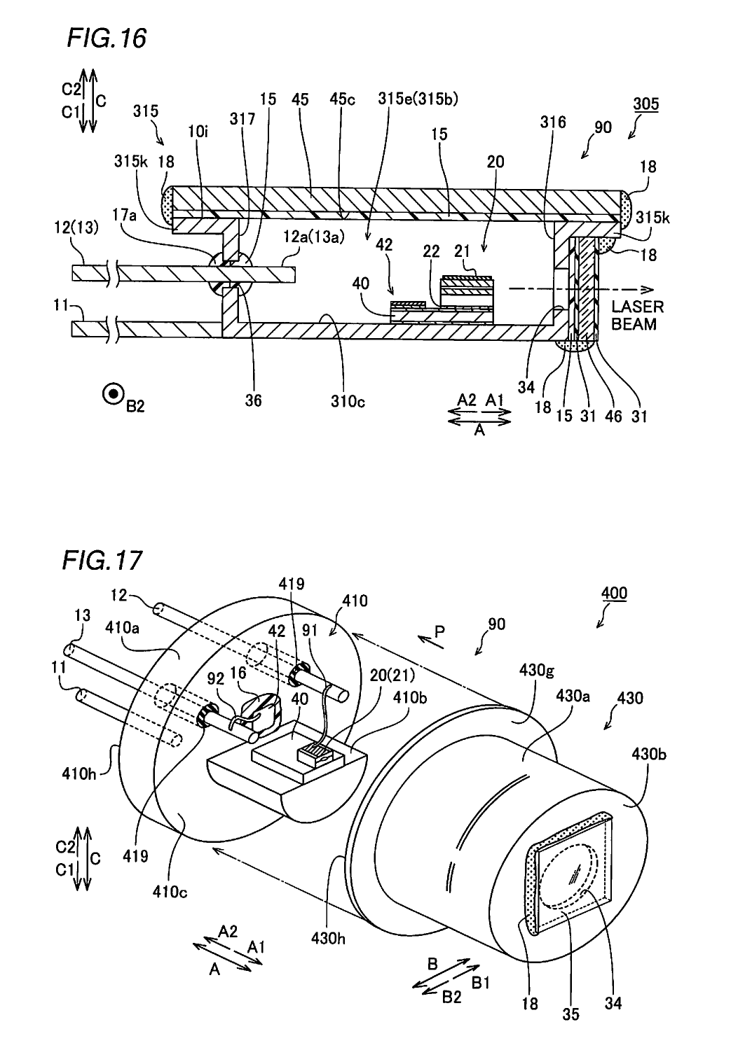

A semiconductor laser apparatus 305 according to a modification of the third embodiment is now described. This semiconductor laser apparatus 305 comprises a base portion 315 prepared by forming a recess portion 315b in a substantially rectangular flat metal plate by press working, as shown in FIG. 15. FIG. 16 includes a sectional view showing a mounting structure of a lead frame 12 (13) and the base portion 315 in a part of a longitudinal sectional view taken along the center line of the semiconductor laser apparatus 305 in a width direction (direction B).

The recess portion 315b is constituted by four side wall portions 316, 317, 318 and 319 surrounding the periphery of the blue-violet semiconductor laser chip 20 and an inner bottom surface 310c for mounting a submount 40. The recess portion 315b has an opening 315e, which opens in an upper surface 10i of the base portion 315. The base portion 315 is provided with a frame-shaped mounting portion 315k extending outward (in directions A and B) along an outer edge of the opening 315e.

A hole 34 is provided in a substantially central portion of the side wall portion 316 in front (on an A1 side) of the blue-violet semiconductor laser chip 20. A window member 46 is bonded through a sealant 15 to cover the hole 34 from the outside (A1 side) of the side wall portion 316.

As shown in FIG. 16, a lead frame 11 is mounted to conduct to the side wall portion 317 in the vicinity of an lower end portion of the side wall portion 317 behind (on an A2 side of) the blue-violet semiconductor laser chip 20. The lead frames 12 and 13 pass through respective holes 36 formed in the side wall portion 317. At this time, sealing members 17a made of epoxy resin are provided in clearances between respective inner peripheral surfaces of the holes 36 and the lead frames 12 and 13 and on an outer surface (on the A2 side) of the side wall portion 317. A sealant 15 is provided on an inner surface (on the A1 side) of the side wall portion 317 from which the lead frames 12 and 13 are exposed to cover edges of the holes 36 and outer peripheral surfaces of the lead frames 12 and 13. Thus, the lead frames 12 and 13 and the base portion 315 are isolated from each other.

A side surface in which the base portion 315 and a sealing member 45 are bonded to each other through the sealant 15 (outer edges of the mounting portion 315k and the sealing member 45) and side surfaces in which the base portion 315 and the window member 46 are bonded to each other through the sealant 15 (a part of a lower surface of the mounting portion 315k and a part on a back surface side of the recess portion 315b) are covered with a covering agent 18 made of a material with smaller water vapor permeability than the sealant 15. Light curing or thermosetting resin made of epoxy resin or the like with low water vapor permeability is employed as this covering agent 18. The covering agent 18 is an example of the “resin made of a material with small water vapor permeability” in the present invention.

The remaining structure of the semiconductor laser apparatus 305 according to the modification of the third embodiment is substantially similar to that of the semiconductor laser apparatus 300 according to the third embodiment and denoted by the same reference numerals in the figures.

In a manufacturing process of the semiconductor laser apparatus 305, the base portion 315 having the recess portion 315b is formed by performing press working on a substantially rectangular metal plate made of phosphor bronze. Thereafter, the single hole 34 is provided in the side wall portion 316, and the two holes 36 are provided in the side wall portion 317. Then, the lead frame 11 is mounted on the lower end portion of the side wall portion 317, and the lead frames 12 and 13 each are fixed with the sealing member 17a in a state where the lead frames 12 and 13 pass through the respective holes 36 above (on a C2 side of) the lead frame 11. Thereafter, the sealant 15 is piled up on portions where the lead frames 12 and 13 pass through the holes 36 inside the side wall portion 317. Then, the covering agent 18 is piled up on the side surface in which the base portion 315 and the sealing member 45 are bonded to each other through the sealant 15 and the side surfaces in which the base portion 315 and the window member 46 are bonded to each other through the sealant 15. The remaining manufacturing process is substantially similar to that of the third embodiment.

According to the modification of the third embodiment, as hereinabove described, the sealant 15 is provided on the inner surface of the side wall portion 317 from which the lead frames 12 and 13 are exposed to cover the edges of the holes 36 and the outer peripheral surfaces of the lead frames 12 and 13. Thus, volatile organic gas generated by the sealing member 17a made of epoxy resin can be inhibited from penetrating into the sealant 15 and entering a package 90.

The side surface in which the base portion 315 and the sealing member 45 are bonded to each other through the sealant 15 and the side surfaces in which the base portion 315 and the window member 46 are bonded to each other through the sealant 15 are covered with the covering agent 18. Thus, the covering member 18 can reliably inhibit moisture or the like existing outside (in the atmosphere) from entering the package 90 through the sealant 15 from the aforementioned bonded portions.

### Fourth Embodiment

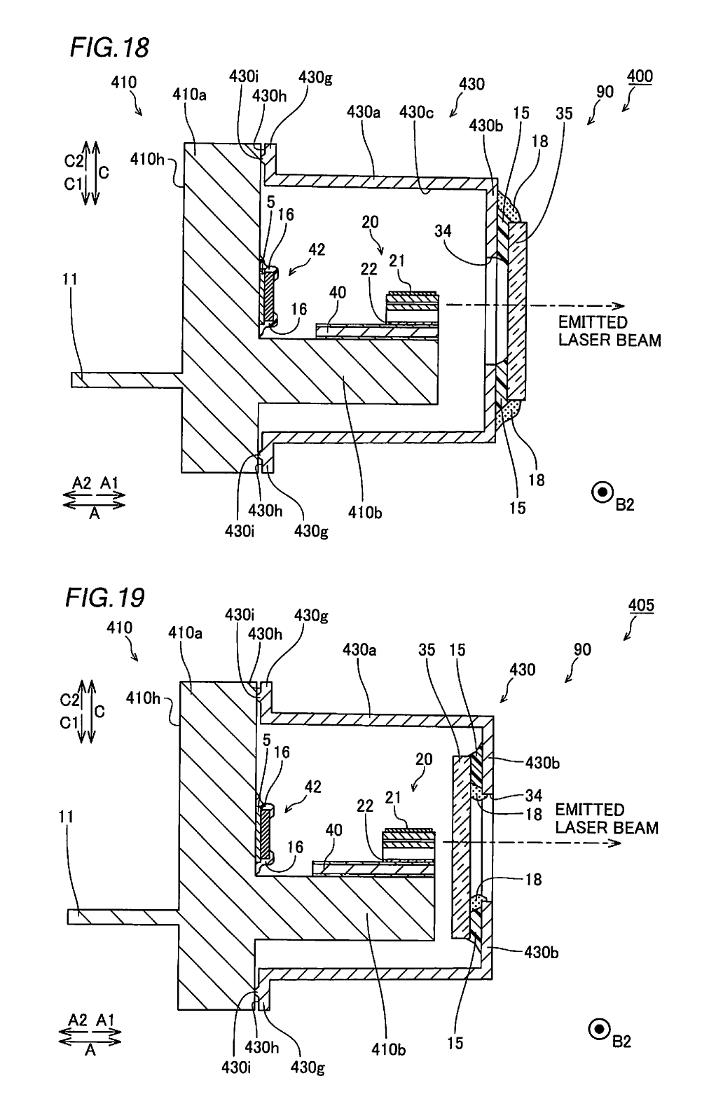

A semiconductor laser apparatus 400 according to a fourth embodiment of the present invention is now described. In this semiconductor laser apparatus 400, as shown in FIGS. 17 and 18, a package 90 is constituted by a metal base portion 410 and a metal cap portion 430. The cap portion 430 is an example of the “sealing member” in the present invention.

The base portion 410 is made of kovar with an Au-plated surface. The base portion 410 has a stem portion 410a with a prescribed thickness (in a direction A) formed in a substantially disc shape and a protruding block 410b protruding forward (in a laser beam-emitting direction (direction A1)), formed on a lower region (C1 side) of a front surface 410c of the stem portion 410a and having a semilunar cross section (in a width direction (direction B)).

The base portion 410 is provided with a lead frame 11 conducting to the stem portion 410a and lead frames 12 and 13 so arranged as to pass through the stem portion 410a from the front side to the back side (A2 side) in a state where the lead frames 12 and 13 are hermetically-closed by low-melting-point glass 419 such as kovar glass and isolated from the lead frame 11. Respective back end regions of the lead frames 11 to 13 extending backward are exposed from a back surface 410h on a back portion of the stem portion 410a.

A blue-violet semiconductor laser chip 20 is mounted on a substantially central portion of an upper surface of the protruding block 410b through a submount 40. A PD 42 is arranged on the front surface 410c of the stem portion 410a at a position opposed to a light-reflecting surface (A2 side) of the blue-violet semiconductor laser chip 20 such that a photoreceiving surface faces forward. A lower surface (n-type region) of the PD 42 is electrically connected to the stem portion 410a through a conductive adhesive layer 5. A covering agent 16 is circumferentially applied to cover the outer periphery of the PD 42 excluding the photoreceiving surface, a surface of the conductive adhesive layer 5 protruding along this outer periphery and a surface of the stem portion 410a in the periphery of the conductive adhesive layer 5.

The cap portion 430 has a body made of kovar with an Ni-plated surface and has a side wall portion 430a substantially cylindrically formed and a bottom portion 430b closing one side (A1 side) of the side wall portion 430a. A mounting portion 430g is circumferentially formed on an opening side (A2 side) of the side wall portion 430a of the cap portion 430. A protrusion 430i employed in resistance welding is formed on an end surface 430h of the mounting portion 430g.

A hole 34 is provided in a substantially central portion of the bottom portion 430b of the cap portion 430. A rectangular light transmission portion 35 made of borosilicate glass is provided to cover the hole 34 from the outside (A1 side) of the bottom portion 430b. At this time, the light transmission portion 35 is bonded to the bottom portion 430b through a sealant 15 with a thickness of about 0.1 mm applied around the hole 34.

As shown in FIG. 18, a covering agent 18 is circumferentially piled up so as to come into contact with the bottom portion 430b, the sealant 15 and the light transmission portion 35 along an outer edge of the light transmission portion 35. In other words, a side surface (outer surface) of the sealant 15 for bonding the bottom portion 430b and the light transmission portion 35 to each other is covered with the covering agent 18, and the sealant 15 is prevented from coming into direct contact with outside air. The covering agent 16 is not applied onto an inner surface 430c of the cap portion 430.

The remaining structure of the semiconductor laser apparatus 400 is substantially similar to that of the semiconductor laser apparatus 100 according to the first embodiment and denoted by the same reference numerals in the figures.

In a manufacturing process of the semiconductor laser apparatus 400, the submount 40 to which the blue-violet semiconductor laser chip 20 is bonded with a conductive adhesive layer (not shown) is bonded onto the protruding block 410b of the base portion 410 provided with the lead frames 11 to 13, as shown in FIG. 17. Then, the lower surface (n-type region) of the PD 42 is bonded onto the front surface 410c behind the submount 40 and above the protruding block 410b with the conductive adhesive layer 5.

Thereafter, the outer periphery of the PD 42 is covered with a film of the covering agent 16 (EVOH resin) previously cut in a frame shape from the upper side of the PD 42 not to come into contact with the photoreceiving surface. In this state, the base portion 410 is heated to about 200° C., whereby the covering agent 16 is melted and circumferentially covers the outer periphery of the PD 42 excluding the photoreceiving surface, the surface of the conductive adhesive layer 5 protruding along this outer periphery and the surface of the stem portion 410a in the periphery of the conductive adhesive layer 5. After cooling the stem portion 410a, metal wires 91 and 92 are bonded.

Meanwhile, the cap portion 430 having the hole 34 in the substantially central portion of the bottom portion 430b is molded with a prescribed mold press apparatus. Thereafter, the sealant 15 is applied around the hole 34 from the outside of the bottom portion 430b in a state where the cap portion 430 is heated to about 220° C. In a state where the sealant 15 is melted by heat, the light transmission portion 35 is press-bonded through the sealant 15 to cover the hole 34, and thereafter the cap portion 430 is cooled. Then, the covering agent 18 is piled up to cover the sealant 15 exposed along the outer edge of the light transmission portion 35. The cap portion 430 is formed in the aforementioned manner.

Finally, the cap portion 430 is mounted on the base portion 410 along arrow P (in the direction A2) shown in FIG. 17. At this time, the end surface 430h of the mounting portion 430g is mounted by resistance welding with a cap seal machine while circumferentially bringing the end surface 430h of the mounting portion 430g into contact with the vicinity of an outer edge of the stem portion 410a. Thus, the blue-violet semiconductor laser chip 20 is hermetically sealed. The remaining manufacturing process is substantially similar to that of the first embodiment. The semiconductor laser apparatus 400 is formed in the aforementioned manner.

According to the fourth embodiment, as hereinabove described, the cap portion 430 is cylindrically formed with the bottom portion 430b, and hence the package 90 can be sealed in a state where the blue-violet semiconductor laser chip 20 is circumferentially surrounded by an inner surface of the side wall portion 430a extending in a longitudinal direction (an extensional direction of a cylindrical shape (direction A)) of the cap portion 430.

The cap portion 430 can be mounted on the stem portion 410a by resistance welding with a cap seal machine conventionally employed even if the cap portion 430 manufactured through the aforementioned method is employed, and hence the semiconductor laser apparatus 400 can be easily manufactured with existing manufacturing equipments without increasing the manufacturing cost. The remaining effects of the fourth embodiment are similar to those of the first embodiment.

### Modification of Fourth Embodiment

A semiconductor laser apparatus 405 according to a modification of a fourth embodiment is now described. In this semiconductor laser apparatus 405, as shown in FIG. 19, a light transmission portion 35 is bonded through a sealant 15 to cover a hole 34 from the inside (A2 side) of a bottom portion 430b of a cap portion 430. A covering agent 18 is circumferentially piled up to come into contact with the hole 34, the sealant 15 and the light transmission portion 35 in the vicinity of an inner surface of the hole 34 on which the light transmission portion 35 is mounted from inside. In other words, a side surface (inner surface) of the sealant 15 bonding the bottom portion 430b and the light transmission portion 35 is covered with the covering agent 18. The remaining structure of the semiconductor laser apparatus 405 according to the modification of the fourth embodiment is substantially similar to that of the semiconductor laser apparatus 400 according to the fourth embodiment and denoted by the same reference numerals in the figure.

In a manufacturing process of the semiconductor laser apparatus 405 according to the modification of the fourth embodiment, the light transmission portion 35 is thermocompression bonded through the sealant 15 from the inside of the press molded cap portion 430, and thereafter the covering agent 18 is piled up to cover the sealant 15 exposed on a side of the inner surface of the hole 34. The remaining manufacturing process is substantially similar to that of the fourth embodiment. The effects of the modification of the fourth embodiment are similar to those of the fourth embodiment.

### Fifth Embodiment

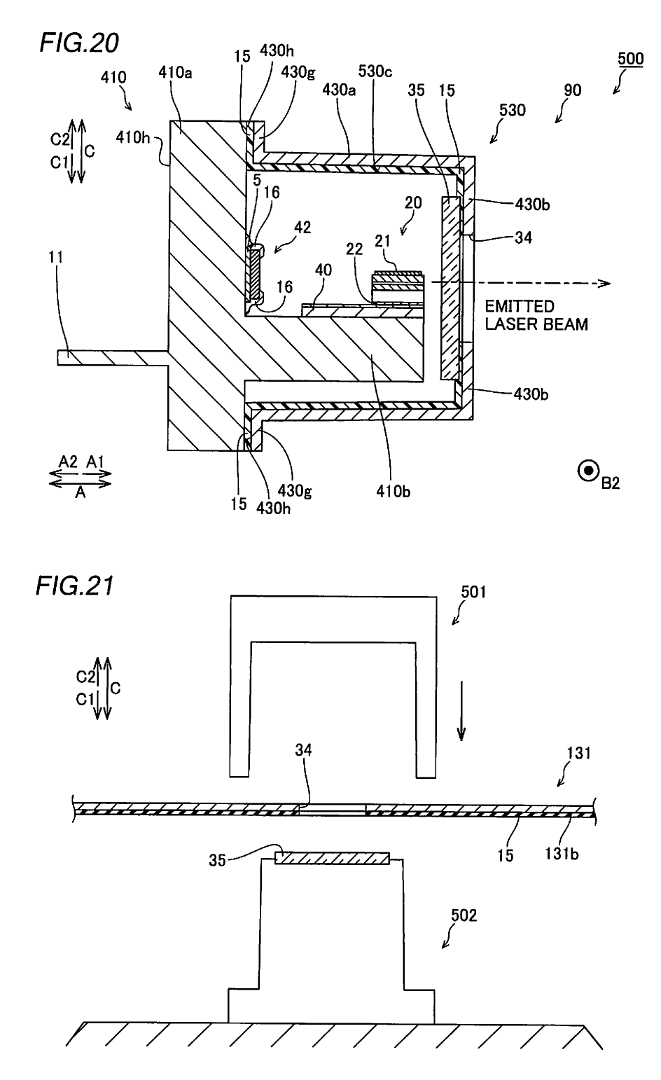

A semiconductor laser apparatus 500 according to a fifth embodiment of the present invention is now described. In this semiconductor laser apparatus 500, as shown in FIG. 20, a package 90 is sealed with a cap portion 530 molded employing a nickel silver sheet having a thickness of about 20 μm. The remaining structure of the semiconductor laser apparatus 500 according to the fifth embodiment is substantially similar to that of the semiconductor laser apparatus 400 according to the fourth embodiment and denoted by the same reference numerals as the modification of the fourth embodiment in the figures. The cap portion 530 is an example of the “sealing member” in the present invention.

The cap portion 530 has a body made of a nickel silver sheet, and a sealant 15 is applied with a thickness of about 0.3 mm on a substantially entire region of an inner surface 530c excluding a hole 34 and an end surface 430h of a mounting portion 430g. In this state, the cap portion 530 and a stem portion 410a are bonded to each other through the sealant 15 in the mounting portion 430g.

In a manufacturing process of the semiconductor laser apparatus 500 according to the fifth embodiment, a nickel silver sheet 131 formed with the hole 34 is prepared, as shown in FIG. 21. Then, in a state where the nickel silver sheet 131 is heated to about 220° C., the sealant 15 is applied with a thickness of about 0.2 mm on an entire lower (back) surface 131b and cooled, and thereafter the hole 34 is formed. Then, in a state where the nickel silver sheet 131 is set such that the sealant 15 faces downward (in a direction C1) between a movable upper mold 501 and a stationary lower mold 502, the movable upper mold 501 is fitted into the stationary lower mold 502. At this time, the nickel silver sheet 131 is molded in a state where a light transmission portion 35 of glass formed in a substantially disc shape is placed on an upper surface (on a C2 side) of the stationary lower mold 502. Drafts are provided on an inner surface of the movable upper mold 501 and an outer surface of the stationary lower mold 502. Thus, in the molded cap portion 530, an outer diameter of a side wall portion 430a (an inner diameter of the inner surface 530c) in the vicinity of the mounting portion 430g is slightly larger than an outer diameter of the side wall portion 430a (an inner diameter of the inner surface 530c) in the vicinity of a bottom portion 430b. Corrugations (not shown) are formed on an outer surface (inner surface) of the nickel silver sheet 131 substantially in the form of a cylinder having a bottom portion (the side wall portion 430a and the mounting portion 430g) by molding the cap portion 530.

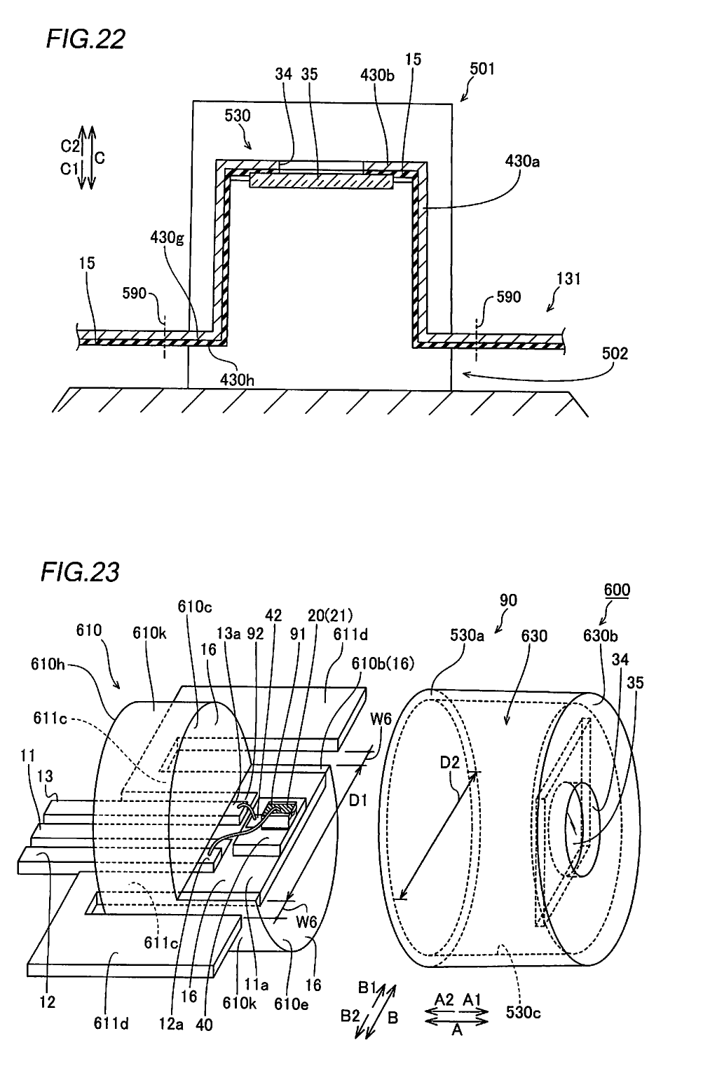

Thereafter, a portion of the nickel silver sheet 131 exposed from a mold is circularly cut along a division line 590 such that the mounting portion 430g remains, as shown in FIG. 22. The cap portion 530 is formed in the aforementioned manner. The nickel silver sheet 131 is an example of the “metal foil” in the present invention.

Finally, the cap portion 530 is mounted on a base portion 410 along a direction (direction A2) shown in FIG. 20. At this time, in a state where the stem portion 410a is heated to about 200° C., the end surface 430h of the mounting portion 430g is thermocompression bonded while circumferentially bringing the end surface 430h of the mounting portion 430g into contact with the vicinity of an outer edge of the stem portion 410a. The remaining manufacturing process is substantially similar to that of the fourth embodiment.

According to the fifth embodiment, as hereinabove described, the cap portion 530 is molded by combining the nickel silver sheet 131 and the sealant 15. In other words, a member easily bends in a prescribed shape in the manufacturing process, whereby the side wall portion 430a and the bottom potion 430b of the cap portion 530 can be simultaneously prepared. The remaining effects of the fifth embodiment are similar to those of the first embodiment.

### Sixth Embodiment

A semiconductor laser apparatus 600 according to a sixth embodiment of the present invention is now described. In this semiconductor laser apparatus 600, as shown in FIG. 23, a package 90 is constituted by a base portion 610 made of resin and a cap portion 630 molded with aluminum foil. The cap portion 630 is an example of the “sealing member” in the present invention.

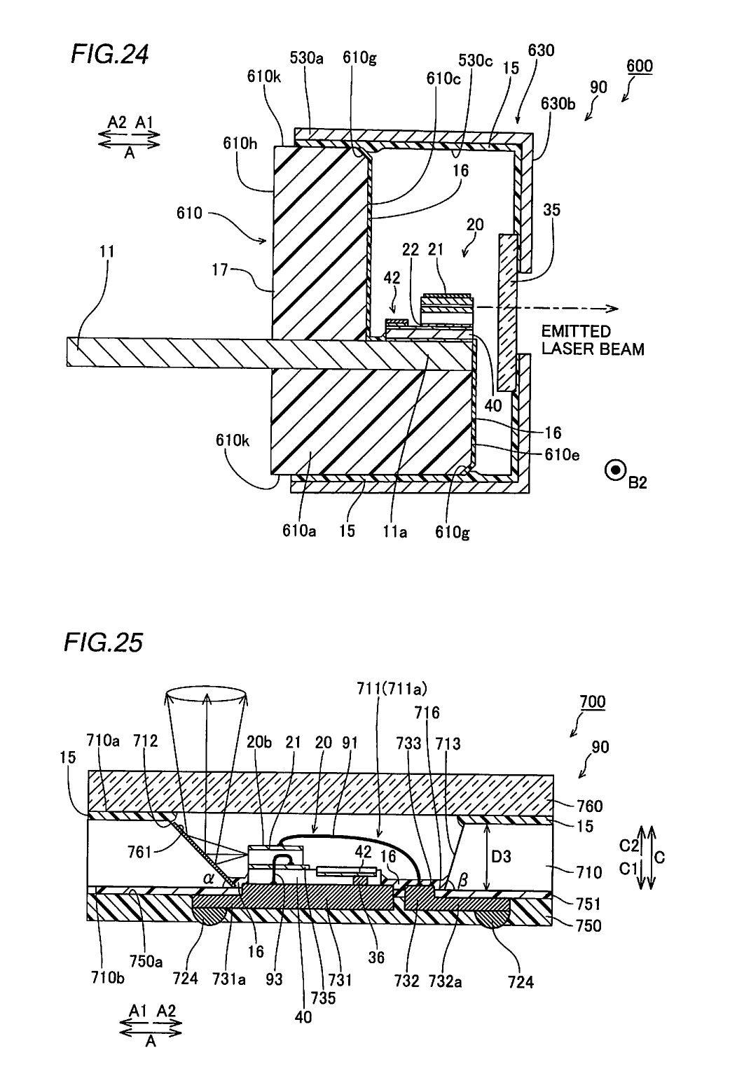

The base portion 610 is made of epoxy resin. The base portion 610 has a substantially cylindrical header portion 610a having an outer diameter D1 and a protruding block 610b extending forward (in an A1 direction) from a lower half portion of the front surface 610c of the header portion 610a. As shown in FIG. 24, edges 610g where an outer peripheral surface 610k and front surfaces 610c and 610e of the base portion 610 intersect are chamfered.

A lead frame 11 is integrally formed with a pair of heat radiation portions 611d connected to a front end region 11a. Specifically, the lead frame 11 is formed with connecting portions 611c extending backward (in a direction A2) from both ends of the front end region 11a in a width direction (on B2 and B1 sides). The connecting portions 611c extend backward from the front end region 11a outside (on the B2 and B1 sides of) lead frames 12 and 13 and pass through a back surface 610h after hiding in the header portion 610a from the front surface 610c of the base portion 610. The heat radiation portions 611d are connected to back end regions of the connecting portions 611c exposed from the back surface 610h of the base portion 610. The heat radiation portions 611d extend forward (in the direction A1) from positions connected to the connecting portions 611c. Therefore, the pair of heat radiation portions 611d extend substantially parallel to the outer peripheral surface 610k at an interval of a width W6 from the outer peripheral surface 610k of the base portion 610, as shown in FIG. 23.

The cap portion 630 is the cap portion 530 of the fifth embodiment from which the mounting portion 430g is removed. An inner diameter D2 of the cap portion 630 is equal to or slightly smaller than the outer diameter D1 of the header portion 610a.

In this state, the header portion 610a is slid to the cap portion 630 from an A2 side toward an A1 side to be fitted into the cap portion 630 in the semiconductor laser apparatus 600, as shown in FIG. 24. In other words, the outer peripheral surface 610k of the header portion 610a and an inner surface 530c of the cap portion 630 are circularly fitted into each other through a sealant 15. Thus, a blue-violet semiconductor laser chip 20 in the package 90 is hermetically sealed.

A covering agent 16 is applied onto a surface of each member located in sealed space of the package 90. Specifically, the covering agent 16 continuously covers the protruding block 610b, the front surface 610c, the front surface 610e and the edges 610g of the base portion 610, a surface of the front end region 11a other than a portion on which a submount 40 is bonded and surfaces of front end regions 12a and 13a. Therefore, the surfaces of the front end regions 12a and 13a bonded with metal wires 91 and 92 in the base portion 610 of resin located in the sealed space (closed space surrounded by the base portion 610 and the cap portion 630) of the package 90 are completely covered with the covering agent 16. It is not necessary to cover a surface of a metal member with the covering agent 16.

Clearances (notches) each having the width W6 larger than a thickness t1 of a side wall portion 530a of the cap portion 630 are formed between the outer periphery surface 610k of the base portion 610 and the heat radiation portions 611d on both sides of the outer periphery surface 610k. Therefore, the heat radiation portions 611d are arranged outside the cap portion 630 without interfering in (coming into contact with) the side wall portion 530a of the cap portion 630 in a state where the cap portion 630 is fitted into the base portion 610. The remaining structure of the semiconductor laser apparatus 600 according to the sixth embodiment is substantially similar to that of the semiconductor laser apparatus 500 according to the fifth embodiment and denoted by the same reference numerals in the figures.

In a manufacturing process of the semiconductor laser apparatus 600 according to the sixth embodiment, the header portion 610a and the cap portion 630 in the aforementioned shapes are molded, and thereafter the base portion 610 is linearly slid to the cap portion 630 to be fitted into the cap portion 630 in a state where the base portion 610 is heated to about 200° C., thereby sealing the package 90. Before the package is sealed, the covering agent 16 is applied onto the protruding block 610b, the front surface 610c, the front surface 610e and the edges 610g of the base portion 610, the surface of the front end region 11a other than the portion on which the submount 40 is bonded and the surfaces of the front end regions 12a and 13a. The remaining manufacturing process is substantially similar to that of the fifth embodiment.

According to the sixth embodiment, as hereinabove described, the blue-violet semiconductor laser chip 20 is sealed by fitting the base portion 610 and the cap portion 630 into each other, whereby the inner surface 530c of the cap portion 630 can be easily brought into close contact with the outer peripheral surface 610k of the base portion 610, and hence the package 90 can be easily sealed. In other words, it is not necessary to employ an additional adhesive or the like for sealing, and hence generation of organic gas can be inhibited. The remaining effects of the sixth embodiment are similar to those of the fifth embodiment.

### Seventh Embodiment

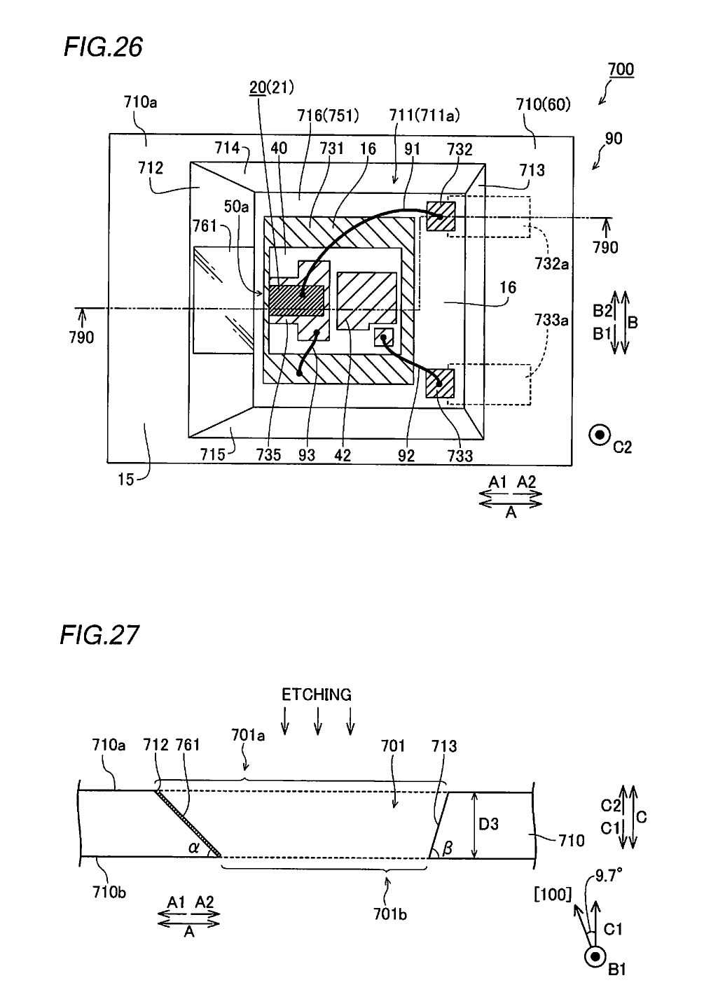

A semiconductor laser apparatus 700 according to a seventh embodiment of the present invention is now described. In this semiconductor laser apparatus 700, package 90 has a base portion 750, an Si (100) substrate 710 mounted on the base portion 750, surrounding a blue-violet semiconductor laser chip 20 from the side (directions A and B) and sealing glass 760 mounted on the Si (100) substrate 710, covering the blue-violet semiconductor laser chip 20 from the upper side (C2 side), as shown in FIG. 25. The Si (100) substrate 710 and the sealing glass 760 are examples of the “sealing member” and the “window member” in the present invention, respectively. FIG. 25 is a sectional view taken along the line 790-790 in FIG. 26.

The base portion 750 is made of an insulating photo solder mask. The photo solder mask denotes an insulating coating of photosensitive resin becoming insoluble in a solvent or the like by structurally changing only a portion exposed to light. The base portion 750 closes an opening 701b (see FIG. 27) on one side (C1 side) of the Si (100) substrate 710 having a through hole 701 (see FIG. 27) penetrating in a thickness direction (direction C). At this time, the base portion 750 is bonded through adhesive resin 751 provided on a lower surface 710b of the Si (100) substrate 710. Thus, a recess portion 711 having an opening 711a which opens on the upper side is constituted by the base portion 750 and the Si (100) substrate 710. The blue-violet semiconductor laser chip 20 is placed on a submount 40 through a pad electrode 735 such that an upper surface 20b is located below (on a C1 side of) an upper surface 710a of the Si (100) substrate 710.

The plate-like (tabular) sealing glass 760 is made of borosilicate glass (hard glass) with a thickness of about 500 μm. The sealing glass 760 is mounted on the upper surface 710a of the Si (100) substrate 710 through a sealant 15. In other words, the Si (100) substrate 710 is covered with the sealing glass 760 from the upper surface 710a so that the opening 711a of the recess portion 711 is closed, and the blue-violet semiconductor laser chip 20 placed on a bottom surface 716 of the recess portion 711 is hermetically sealed in the package 90. A planar shape of the sealing glass 760 is substantially identical to that of the Si (100) substrate 710.

As shown in FIG. 25, in a manufacturing process described later, the Si (100) substrate 710 having a main surface (upper surface 710a) inclined at about 9.7° with respect to a substantially (100) plane is anisotropically etched, whereby four inner surfaces 712, 713, 714 and 715 each having an Si (111) plane are formed on the Si (100) substrate 710. This Si (100) substrate 710 having the main surface inclined at about 9.7° is employed, whereby the inner surface 712 is inclined with an inclined angle α of about 45° with respect to an upper surface 750a (bottom surface 716) of the base portion 750 while the inner surface 713 is inclined with an inclined angle β of about 64.4° with respect to the upper surface 750a (bottom surface 716). The inner surfaces 714 and 715 (see FIG. 26) each are inclined with an inclined angle of about 54.7° with respect to the upper surface 750a (bottom surface 716).

The four inner surfaces 712, 713, 714 and 715 and the adhesive resin 751 formed on an upper surface (surface on the C2 side) of the base portion 750 constitute the recess portion 711. The adhesive resin 751 is employed to bond the Si (100) substrate 710 and the base portion 750, and the bottom surface 716 of the recess portion 711 is substantially constituted by a part of an upper surface of the adhesive resin 751, as shown in FIG. 25. The Si (100) substrate 710 has high resistivity (an insulating property) and a thickness of about 500 μm from the upper surface 710a to the lower surface 710b.

A wiring electrode 731 made of Cu or the like for die-bonding (bonding) the submount 40 is formed on a region (region becoming the bottom surface 716 of the recess portion 711) of the upper surface 750a of the base portion 750 (adhesive resin 751) exposed in the recess portion 711. Thus, a back surface (surface on the C2 side) of the submount 40 is bonded onto a surface of the wiring electrode 731 through a conductive adhesive layer (not shown) at a position deviating to an A1 side (a side closer to the inner surface 712) from a substantially central portion in the recess portion 711. The wiring electrode 731 exposed in the recess portion 711 has a larger plane area than the submount 40, and the submount 40 is placed in a region formed with the wiring electrode 731. The wiring electrode 731 has an extraction wiring portion 731a extending along an A1 direction from a position on which the submount 40 is placed.

A metal reflective film 761 is formed on a surface of a region of the inner surface 712 opposed to a light-emitting surface. Thus, in the semiconductor laser apparatus 700, a laser beam emitted in the direction A1 from the light-emitting surface of the blue-violet semiconductor laser chip 20 is reflected upward on the inner surface 712 (metal reflective film 761) of the recess portion 711, and thereafter transmitted through the sealing glass 760 to be emitted outward. The inner surface 712 and the metal reflective film 761 constitute reflecting means for reflecting the laser beam outward.

As shown in FIG. 26, wiring electrodes 732 and 733 for wire bonding each having a rectangular shape (a size of about 100 μm×about 100 μm) are formed on a region of the bottom surface 716 of the recess portion 711 not formed with the wiring electrode 731. In other words, the wiring electrode 732 is exposed in a region deviating to the inner surface 714 (B2 side) between the submount 40 and the inner surface 713, and the wiring electrode 733 is exposed in a region deviating to the inner surface 715 (B1 side) between the submount 40 and the inner surface 713. The wiring electrodes 732 and 733 have extraction wiring portions 732a and 733a extending along a direction A2.

Therefore, a first end of a metal wire 91 is bonded to a p-side electrode 21 formed on an upper surface of the blue-violet semiconductor laser chip 20, and a second end of the metal wire 91 is connected to the wiring electrode 732. A first end of a metal wire 92 is bonded to an upper surface (p-type region) of the PD 42, and a second end of the metal wire 92 is connected to the wiring electrode 733. A first end of a metal wire 93 is bonded to the pad electrode 735 onto which a lower surface of the blue-violet semiconductor laser chip 20 is bonded, and a second end of the metal wire 93 is connected to the wiring electrode 731. The PD 42 is formed such that a lower surface (n-type region) and the wiring electrode 731 conduct with each other through an electrode 36 passing through the submount 40 vertically (in the direction C). A solder ball 724 made of Au—Sn solder is formed on an end of each of the extraction wiring portions 731a, 732a and 733a.

A covering agent 16 is applied with a prescribed thickness onto a surface of each member located in sealed space of the package 90. Specifically, the covering agent 16 continuously covers a surface of the adhesive resin 751 in the recess portion 711, a surface of the wiring electrode 731 other than portions to which the submount 40 and the PD 42 are bonded and surfaces of the wiring electrodes 732 and 733. Therefore, surfaces of the base portion 750, the wiring electrodes 731 to 733, etc. located in the sealed space of the package 90 are completely covered with the covering agent 16. The remaining structure of the seventh embodiment is substantially similar to that of the first embodiment.

A manufacturing process of the semiconductor laser apparatus 700 according to the seventh embodiment is now described with reference to FIGS. 25 to 29.

As shown in FIG. 27, the Si (100) substrate 710 in a wafer state having a thickness D3 of about 500 μm and the main surface (upper surface 710a) inclined at about 9.7° with respect to the substantially (100) plane is prepared. Then, wet etching (anisotropic etching) employing an etching solution such as TMAH is performed on the Si (100) substrate 710 formed with an etching mask (not shown) having a prescribed mask pattern on the upper surface 710a, thereby forming the through hole 701 penetrating from the upper surface 710a to the lower surface 710b. Thus, a plurality of the through holes 701 having openings 701a and 701b are formed in the Si (100) substrate 710 in a wafer state.

At this time, the four different inner surfaces 712, 713, 714 and 715 are formed in the through hole 701 by etching corresponding to crystal orientation of Si. The inner surface 712 is an etched surface (inclined surface) inclined at about 45° (angle α) with respect to the upper surface 710a, and the inner surface 713 is an etched surface (inclined surface) inclined at about 64.4° (angle β) with respect to the upper surface 710a. The inner surfaces 714 and 715 (see FIG. 26) are etched surfaces inclined at about 54.7° with respect to the upper surface 710a of the Si (100) substrate 710.

Thereafter, the metal reflective film 761 is formed by evaporation, sputtering or the like on the region of the inner surface 712 opposed to the light-emitting surface (see FIG. 25) in a state where the blue-violet semiconductor laser chip 20 is placed.

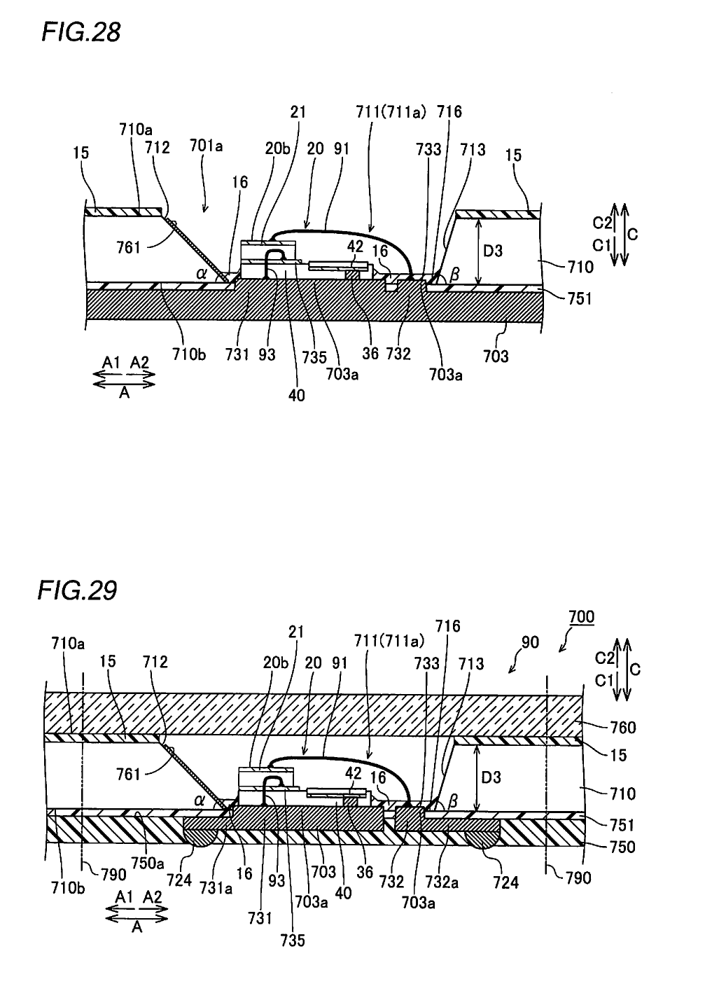

Meanwhile, a tabular copper plate 703 having a thickness of about 100 μm is prepared, as shown in FIG. 28. The etching mask (not shown) having a prescribed mask pattern is formed on an upper surface of the copper plate 703, and thereafter wet etching employing an etching solution such as a ferric chloride solution is performed on the copper plate 703. Thus, the copper plate 703 is etched from the upper and lower surfaces so that the flat portion has a thickness of about 60 μm, and a protrusion 703a having a protrusion height of about 20 μm is formed on the upper surface (a surface on the C2 side).

Thereafter, the thermosetting epoxy resin-based adhesive resin 751 is bonded onto the upper surface of the copper plate 703 by lamination with a roll laminator or a hot pressing machine. At this time, the adhesive resin 751 is bonded at a temperature of not more than about 100° C. at which the adhesive resin 751 does not harden completely. Thereafter, a portion of the adhesive resin 751 covering the protrusion 703a is removed by O₂ plasma treatment, polishing or the like.

Then, as shown in FIG. 28, the copper plate 703 is bonded onto the lower surface 710b of the Si (100) substrate 710 having the through hole 701 through the adhesive resin 751, and thereafter the Si (100) substrate 710 and the copper plate 703 are bonded to each other by thermocompression bonding for 5 minutes under temperature and pressure conditions of about 200° C. and about 1 Mpa. Thus, the opening 701b (see FIG. 27) of the Si (100) substrate 710 is closed so that the recess portion 711 is formed. The opening 701a of the Si (100) substrate 710 is left as the opening 711a in the upper portion of the recess portion 711.

Thereafter, the submount 40 to which the blue-violet semiconductor laser chip 20 is previously bonded is bonded onto the surface of the wiring electrode 731. Then, the p-side electrode 21 of the blue-violet semiconductor laser chip 20 and the wiring electrode 732 are connected with each other through the metal wire 91, and the p-type region of the PD 42 and the wiring electrode 733 are connected with each other through the metal wire 92. The pad electrode 735 and the wiring electrode 731 are connected with each other through the metal wire 93 (see FIG. 26). Before the metal wires 91 and 92 are bonded to the wiring electrodes 732 and 733, a metal film made of Au or the like may be formed on the surfaces of the wiring electrodes 732 and 733. Thereafter, the covering agent 16 is applied onto the aforementioned surfaces of the members in the recess portion 711 in a state where the Si (100) substrate 710 is heated to about 230° C.

Thereafter, the sealing glass 760 having a thickness of about 500 μm is bonded to the recess portion 711 of the Si (100) substrate 710 from the upper side by thermocompression bonding, as shown in FIG. 29. At this time, the Si (100) substrate 710 and the sealing glass 760 are bonded to each other through the sealant 15 under a temperature condition of at least about 200° C. and not more than about 220° C. Thus, the sealing glass 760 is bonded to the Si (100) substrate 710 through the sealant 15 in the upper surface 710a surrounding the opening 711a of the recess portion 711, and hence the inside of the recess portion 711 is hermetically sealed.

Thereafter, the lower surface of the copper plate 703 is etched to form a wiring pattern. Thus, the copper plate 703 other than the protrusion 703a has a thickness of about 20 μm. Further, an etching mask (not shown) having a prescribed mask pattern is formed on the lower surface of the copper plate 703, and thereafter wet etching employing a ferric chloride solution is performed on the copper plate 703, thereby forming the wiring electrodes 731 to 733 having prescribed wiring patterns constituted by the extraction wiring portions 731a, 732a and 733a (see FIG. 29). At this time, the adhesive resin 751 is partially exposed from under the removed copper plate 703.

Thereafter, a photo solder mask having a thickness of about 30 μm is formed on the lower surfaces of the wiring electrodes 731 to 733 and the exposed adhesive resin 751 to cover the lower surfaces of the wiring electrodes 731 to 733, as shown in FIG. 29. At this time, a laminated film of a photo solder mask may be bonded, or a liquid photo solder mask may be applied. Then, a lower surface of the photo solder mask is partially removed, and the solder balls 724 are formed on the ends of the extraction wiring portions 731a, 732a and 733a (see FIG. 26) exposed from the photo solder mask. The base portion 750 is formed in the aforementioned manner.

Finally, in a region outside a region formed with the recess portion 711, the sealing glass 760 and the Si (100) substrate 710 are cut (diced) in the thickness direction (direction C) along division lines 790 shown in FIG. 29 with a diamond blade. The semiconductor laser apparatus 700 according to the seventh embodiment shown in FIG. 26 is formed in the aforementioned manner.

According to the seventh embodiment, as hereinabove described, the semiconductor laser apparatus 700 comprises the Si (100) substrate 710 formed with the through hole 701 penetrating in the thickness direction, the sealing glass 760 mounted on the upper surface 710a of the Si (100) substrate 710, sealing the opening 701a (711a) of the through hole 701, the base portion 750 mounted on the lower surface 710b of the Si (100) substrate 710, sealing the opening 701b of the through hole 701 and the blue-violet semiconductor laser chip 20 placed on the surface of the wiring electrode 731 formed on the base portion 750 exposed in the opening 701b through the submount 40. Thus, the upper surface 20b of the blue-violet semiconductor laser chip 20 placed on the surface of the wiring electrode 731 exposed in the opening 701b does not protrude outward (to the C2 side in FIG. 25) beyond the opening 701a (711a), and hence the blue-violet semiconductor laser chip 20 can operate in a state where the same is hermetically sealed in the through hole 701 by the base portion 750 and the sealing glass 760. Thus, the blue-violet semiconductor laser chip 20 is not influenced by moisture in the atmosphere or an organic substance existing in the periphery of the semiconductor laser apparatus 700, and hence reduction of the reliability of the blue-violet semiconductor laser chip 20 can be inhibited.

The laser beam emitted from the blue-violet semiconductor laser chip 20 is reflected by the metal reflective film 761 formed on the inner surface 712 of the through hole 701, and thereafter transmitted through the sealing glass 760 to be emitted outward. Thus, the inner surface 712, which is a part of the through hole 701 of the Si (100) substrate 710 fixed onto the base portion 750 on which the blue-violet semiconductor laser chip 20 is placed through the submount 40, can also serve the reflecting means of the laser beam. In other words, precision of an optical axis of the laser beam reflected by the metal reflective film 761 formed on the inner surface 712 depends only on an arrangement error in placing the blue-violet semiconductor laser chip 20 on the surface of the wiring electrode 731 formed on the base portion 750 through the submount 40, and hence the number of factors causing deviation of the optical axis is reduced so that the magnitude of the deviation of the optical axis can be reduced.

The semiconductor laser apparatus 700 comprises the Si (100) substrate 710 formed with the through hole 701, the base portion 750 mounted on the lower surface 710b of the Si (100) substrate 710, sealing the opening 701b of the through hole 701 and the blue-violet semiconductor laser chip 20 placed on the surface of the wiring electrode 731 exposed in the opening 701b. Thus, a support base on which the blue-violet semiconductor laser chip 20 is placed can be formed as a different member employing a different material from the Si (100) substrate 710, and hence the strength of the semiconductor laser apparatus 700 can be further secured. In the manufacturing process, the Si (100) substrate 710 formed with the through hole 701 and the tabular base portion 750 are bonded to each other through the adhesive resin 751, whereby the package 90 for placing the blue-violet semiconductor laser chip 20 inside can be easily formed.

When wet etching is performed on the Si (100) substrate 710, the through hole 701 passing through the Si (100) substrate 710 is formed thereby forming the inner surfaces 712, 713, 714 and 715, and hence dispersion of the etching depth resulting when wet etching stops in the substrate does not result. Further, the blue-violet semiconductor laser chip 20 placed on the base portion 750 (copper plate 703) can be placed in the recess portion 711 in a state where precision of arrangement is excellent. Thus, in the manufacturing process, deviation of the optical axis of the laser beam and dispersion of the distance from the light-emitting surface to the metal reflective film 761 resulting from an angle (angle in a vertical direction with respect to a cavity direction or a width direction) in which the blue-violet semiconductor laser chip 20 is placed can be effectively inhibited.

The blue-violet semiconductor laser chip 20 is placed on the wiring electrode 731 (copper plate 703) having excellent thermal conductivity through the submount 40, and hence heat of the blue-violet semiconductor laser chip 20 can be efficiently radiated through the wiring electrode 731 (copper plate 703).

The Si (100) substrate 710 having the main surface inclined at about 9.7° with respect to the substantially (100) plane is employed, whereby the four inner surfaces 712 to 715 can be formed simultaneously with wet etching when the through hole 701 is formed in the Si (100) substrate 710 by the wet etching. Consequently, the manufacturing process is simplified, and hence the semiconductor laser apparatus 700 can be efficiently manufactured.

The plurality of through holes 701 are simultaneously formed in the Si (100) substrate 710 in a wafer state, whereby the plurality of through holes 701 can be simultaneously formed through a single etching step, and hence the semiconductor laser apparatus 700 can be efficiently manufactured.

The sealing glass 760 in a wafer state is bonded to a wafer in which the blue-violet semiconductor laser chip 20 is placed on the bottom surface 716 of each of a plurality of the recess portions 711 (wafer in which the base portion 750 is bonded to the Si (100) substrate 710) by thermocompression bonding, thereby sealing the recess portions 711. Thus, the plurality of recess portions 711 can be simultaneously hermetically sealed through a step of bonding a single piece of the sealing glass 760, and hence the semiconductor laser apparatus 700 can be efficiently manufactured. The remaining effects of the seventh embodiment are similar to those of the first embodiment.

### Eighth Embodiment

An optical pickup 800 according to an eighth embodiment of the present invention is now described. The optical pickup 800 is an example of the “optical apparatus” in the present invention.

The optical pickup 800 comprises a three-wavelength semiconductor laser apparatus 805, an optical system 820 adjusting a laser beam emitted from the three-wavelength semiconductor laser apparatus 805 and a light detection portion 830 receiving the laser beam, as shown in FIG. 31.

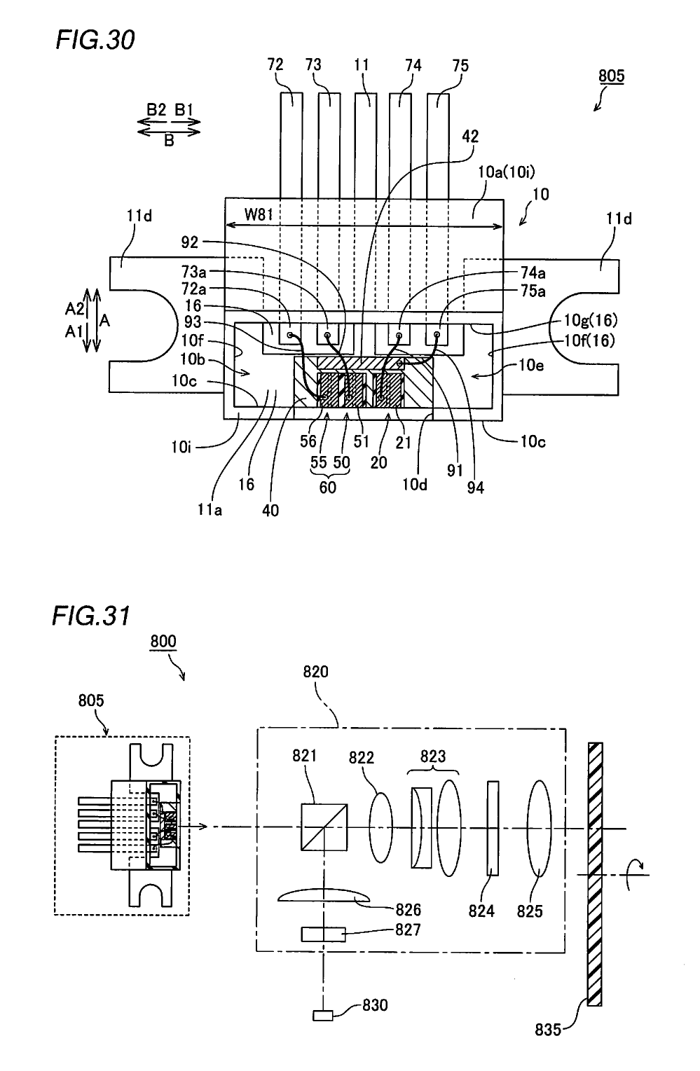

The three-wavelength semiconductor laser apparatus 805 is loaded with a blue-violet semiconductor laser chip 20 and a two-wavelength semiconductor laser chip 60 having a red semiconductor laser element 50 with a lasing wavelength of about 650 nm and an infrared semiconductor laser element 55 with a lasing wavelength of about 780 nm monolithically formed on a submount 40 in a package 90 adjacent to the blue-violet semiconductor laser chip 20, as shown in FIG. 30. The three-wavelength semiconductor laser apparatus 805 is an example of the “semiconductor laser apparatus” in the present invention, and the red semiconductor laser element 50, the infrared semiconductor laser element 55 and the two-wavelength semiconductor laser chip 60 are an example of the “semiconductor laser chip” in the present invention.

A base portion 10 is provided with lead frames 11, 72, 73, 74 and 75 made of metal. These lead frames 11 and 72 to 75 are so arranged as to pass through the base portion 10 from the front side (A1 side) to the back side (A2 side) in a state of being isolated from each other by resin mold. Back end regions extending to the outside (A2 side) of the base portion 10 each are connected to a driving circuit (not shown). Front end regions 11a, 72a, 73a, 74a and 75a extending to the front side of the lead frames 11 and 72 to 75 are exposed from an inner wall portion 10g and arranged on a bottom surface of a recess portion 10b.

A first end of a metal wire 91 is bonded to a p-side electrode 21, and a second end of the metal wire 91 is connected to the front end region 74a of the lead frame 74. A first end of a metal wire 92 is bonded to a p-side electrode 51 formed on an upper surface of the red semiconductor laser element 50, and a second end of the metal wire 92 is connected to the front end region 73a of the lead frame 73. A first end of a metal wire 93 is bonded to a p-side electrode 56 formed on an upper surface of the infrared semiconductor laser element 55, and a second end of the metal wire 93 is connected to the front end region 72a of the lead frame 72. An n-side electrode (not shown) formed on a lower surface of the blue-violet semiconductor laser chip 20 and an n-side electrode (not shown) formed on a lower surface of the two-wavelength semiconductor laser chip 60 are electrically connected to the front end region 11a of the lead frame 11 through the submount 40.

A first end of a metal wire 94 is bonded to an upper surface of a PD 42, and a second end of the metal wire 94 is connected to the front end region 75a of the lead frame 75.

A cross section of the base portion 10 is elongated in a width direction (direction B), whereby a base body 10a has a maximum width W81 (W81>W1), as compared with the semiconductor laser apparatus 100 according to the first embodiment. Therefore, an opening 10d in a front portion of the recess portion 10b is also elongated in the direction B. The remaining structure of the three-wavelength semiconductor laser apparatus 805 is substantially similar to that of the semiconductor laser apparatus 100 according to the first embodiment, and the structure similar to that of the first embodiment is denoted by the same reference numerals in the figure.

In a manufacturing process of the three-wavelength semiconductor laser apparatus 805, the blue-violet semiconductor laser chip 20 and the two-wavelength semiconductor laser chip 60 are aligned in a lateral direction (direction B in FIG. 30) and bonded through the submount 40. Thereafter, the respective p-side electrodes 21, 51 and 56 of the laser chips 20 and 60 and the upper surface of the PD 42 and the front end regions 72a, 73a, 74a and 75a of the lead frames 72, 73, 74 and 75 are wire-bonded to each other. The remaining manufacturing process is substantially similar to that of the first embodiment.

The optical system 820 has a polarizing beam splitter (PBS) 821, a collimator lens 822, a beam expander 823, a λ/4 plate 824, an objective lens 825, a cylindrical lens 826 and an optical axis correction device 827.

The PBS 821 totally transmits the laser beam emitted from the three-wavelength semiconductor laser apparatus 805, and totally reflects a laser beam fed back from an optical disc 835. The collimator lens 822 converts the laser beam emitted from the three-wavelength semiconductor laser apparatus 805 and transmitted through the PBS 821 to a parallel beam. The beam expander 823 is constituted by a concave lens, a convex lens and an actuator (not shown). The actuator has a function of correcting a wavefront state of the laser beam emitted from the three-wavelength semiconductor laser apparatus 805 by varying a distance between the concave lens and the convex lens in response to servo signals from a servo circuit described later.

The λ/4 plate 824 converts the linearly polarized laser beam, substantially converted to the parallel beam by the collimator lens 822, to a circularly polarized beam. Further, the λ/4 plate 824 converts the circularly polarized laser beam fed back from the optical disc 835 to a linearly polarized beam. In this case, a direction of polarization of the linearly polarized beam is orthogonal to a direction of polarization of the linearly polarized laser beam emitted from the three-wavelength semiconductor laser apparatus 805. Thus, the PBS 821 substantially totally reflects the laser beam fed back from the optical disc 835. The objective lens 825 converges the laser beam transmitted through the λ/4 plate 824 on a surface (recording layer) of the optical disc 835. The objective lens 825 is movable in a focus direction, a tracking direction and a tilt direction by an objective lens actuator (not shown) in response to the servo signals (a tracking servo signal, a focus servo signal and a tilt servo signal) from the servo circuit described later.

The cylindrical lens 826, the optical axis correction device 827 and the light detection portion 830 are arranged to be along an optical axis of the laser beam totally reflected by the PBS 821. The cylindrical lens 826 provides the incident laser beam with astigmatic action. The optical axis correction device 827 is formed by diffraction grating and so arranged that a spot of zeroth-order diffracted light of each of blue-violet, red and infrared laser beams transmitted through the cylindrical lens 826 coincides with each other on a detection region of the light detection portion 830 described later.

The light detection portion 830 outputs a playback signal on the basis of an intensity distribution of the received laser beam. The light detection portion 830 has a detection region of a prescribed pattern, to obtain a focus error signal, a tracking error signal and a tilt error signal along with the playback signal. The optical pickup 800 comprising the three-wavelength semiconductor laser apparatus 805 is constituted in the aforementioned manner.

In this optical pickup 800, the three-wavelength semiconductor laser apparatus 805 can independently emit blue-violet, red and infrared laser beams from the blue-violet semiconductor laser chip 20, the red semiconductor laser element 50 and the infrared semiconductor laser element 55 by independently applying voltages between the lead frame 11 and the respective lead frames 72 to 74. As hereinabove described, the laser beams emitted from the three-wavelength semiconductor laser apparatus 805 are adjusted by the PBS 821, the collimator lens 822, the beam expander 823, the λ/4 plate 824, the objective lens 825, the cylindrical lens 826 and the optical axis correction device 827, and thereafter irradiated on the detection region of the light detection portion 830.

When data recorded in the optical disc 835 is play backed, the laser beams are applied to the recording layer of the optical disc 835 while controlling laser power emitted from the blue-violet semiconductor laser chip 20, the red semiconductor laser element 50 and the infrared semiconductor laser element 55 to be constant and the playback signal outputted from the light detection portion 830 can be obtained. The actuator of the beam expander 823 and the objective lens actuator driving the objective lens 825 can be feedback-controlled by the focus error signal, the tracking error signal and the tilt error signal simultaneously outputted.

When data is recorded in the optical disc 835, the laser beams are applied to the optical disc 835 while controlling laser power emitted from the blue-violet semiconductor laser chip 20 and the red semiconductor laser element 50 (infrared semiconductor laser element 55) on the basis of data to be recorded. Thus, the data can be recorded in the recording layer of the optical disc 835. Similarly to the above, the actuator of the beam expander 823 and the objective lens actuator driving the objective lens 825 can be feedback-controlled by the focus error signal, the tracking error signal and the tilt error signal outputted from the light detection portion 830.

Thus, record in the optical disc 835 and playback can be performed with the optical pickup 800 comprising the three-wavelength semiconductor laser apparatus 805.

The optical pickup 800 comprises the aforementioned three-wavelength semiconductor laser apparatus 805. In other words, the blue-violet semiconductor laser chip 20 and the two-wavelength semiconductor laser chip 60 are reliably sealed in the package 90. Thus, the reliable optical pickup 800 having the semiconductor laser chips hard to deteriorate, capable of enduring the use for a long time can be obtained. The effects of the three-wavelength semiconductor laser apparatus 805 are similar to those of the semiconductor laser apparatus 100 according to the first embodiment.

Although the present invention has been described and illustrated in detail, it is clearly understood that the same is by way of illustration and example only and is not to be taken by way of limitation, the spirit and scope of the present invention being limited only by the terms of the appended claims.

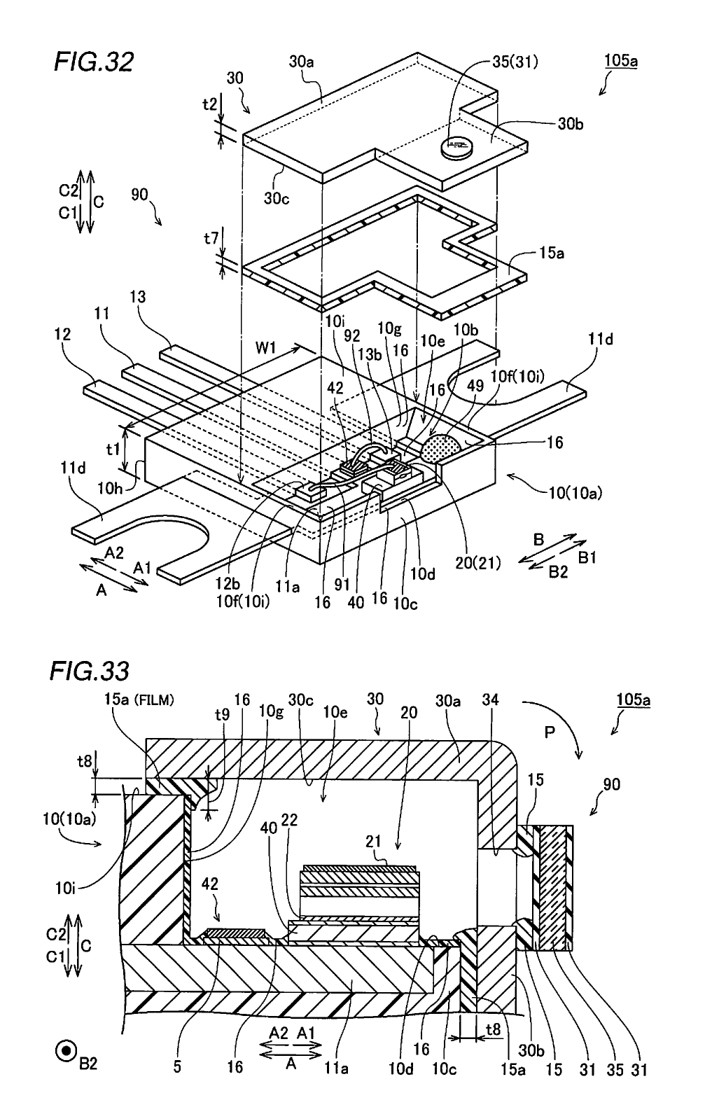

For example, while the sealant 15 having the thickness t3 (about 0.2 mm) is applied onto the surface of either the “sealing member” or the “base portion” in the present invention, and thereafter other members are thermocompression bonded to seal the package in the manufacturing process of each of the first to third and fifth to seventh embodiments, the present invention is not restricted to this. A film sealant 15a cut in a size of the bonded region of the “sealing member” and the “base portion” may be employed in place of the sealant 15 for bonding. For example, in a manufacturing process of a semiconductor laser apparatus 105a, the film sealant 15a cut in an outer shape of the sealing member 30 is sandwiched between the back surface (lower surface) of the sealing member 30 in a state where the sealant 15 is not applied and the upper surface 10i of the base portion 10, and the sealing member 30 and the base portion 10 are thermocompression bonded to each other, as in a modification shown in FIG. 32. At this time, the sealant 15a may be arranged only on the bonded region of the sealing member 30 and the base portion 10. Therefore, a portion of the sealant 15a corresponding to a portion of the sealing member 30 exposed in the sealed space after bonding is preferably previously cut out. Thus, as shown in FIG. 33, the sealing member 30 is bonded to the peripheral region of the opening 10e through the sealant 15a, and thereafter the front surface portion 30b is bent along arrow P and bonded to the peripheral region of the opening 10d.

A thickness t7 of the film sealant 15a is smaller than the thickness t3 (see FIG. 2) in a case where the melted sealant 15 is applied (t7<t3). A thinner thickness t8 of the sealant 15a in the bonded region after bonding means more excellent sealability (airtightness) and can suppress the height (thickness) of the overall package 90. However, when the thickness of the sealant 15a is reduced too much, the sealant 15a is easily influenced by warpage of bonded members or corrugations on the bonded surface, and hence a uniform bonding state of the sealant 15a is hardly obtained. Even if moldability (extrusion moldability) of the film is excellent, a range appropriate for the thickness t7 of the sealant 15a exists. In this case, the thickness t8 of the sealant 15a in the bonded region after bonding is preferably at least about 5 μm and not more than about 50 μm, and more preferably at least about 5 μm and not more than about 30 μm. In this case, the thickness t7 of the film sealant 15a before thermocompression bonding is preferably at least about 5 μm and not more than about 50 μm, and more preferably at least about 5 μm and not more than about 30 μm.

Also when the film sealant 15a is employed for bonding, the sealant 15a may protrude in the form of a fillet inward and outward beyond the bonded region, as shown in FIG. 33, similarly to the semiconductor laser apparatus 100 (see FIG. 2). A thickness t9 in a portion of the sealant 15a protruding in the form of a fillet is much smaller than the thickness t5 (see FIG. 2) in the protruding portion of the sealant 15 in the semiconductor laser apparatus 100 (t9<t5). The portion of the sealant 15a protruding from the bonded region aggregates and slightly shrinks by heat, and hence an amount of the sealant 15a protruding into the sealed space of the package 90 is reduced.

The film sealant 15a can be employed not only for the aforementioned bonding of the sealing member 30 and the base portion 10 but also for bonding of the sealing member 30 and the light transmission portion 35 sealing the hole 34. In other words, the members are thermocompression bonded to each other in a state where the sealant 15a cut in a annular shape is sandwiched between the front surface portion 30b of the sealing member 30 corresponding to the periphery of the hole 34 and the light transmission portion 35 in a substantially disc shape, whereby the hole 34 can be closed by the light transmission portion 35.

In order to confirm usefulness of employing the film sealant 15a, an operation test by APC was performed on the semiconductor laser apparatus 105a under the aforementioned conditions similar to those for the semiconductor laser apparatus 100. Consequently, a chronological change of the operating current of the laser chip in an example was not remarkably different from that in a comparative example even after 1500 hours. Therefore, it has been confirmed that the film sealant 15a can be employed to bond the members to each other in place of applying the sealant 15.

While the film sealant 15a cut out to accurately correspond to the bonded region of the sealing member 30 and the base portion 10 is employed as the aforementioned sealant 15a, the aforementioned modification is not restricted to this, but the inside of the film may not be cut out except for a portion where the window member through which the laser beam penetrates is arranged.

While the sealant 15 is applied onto the substantially entire back surface 45c of the sealing member 45 in the second embodiment, the present invention is not restricted to this, but the sealant 15 may not be applied onto the back surface 45c of the sealing member 45 located in the sealed space of the package 90 so that the surface of the nickel silver sheet may be exposed in the sealed space, similarly to the modification of the first embodiment.

While the gas absorbent 49 is not provided in the package 90 in each of the second to seventh embodiments, the present invention is not restricted to this, but the gas absorbent 49 may be provided, similarly to the first embodiment. For example, synthetic zeolite, calcium oxide-based absorbent material, activated charcoal or the like other than silica gel may be employed as the gas absorbent 49. Synthetic zeolite in the form of a pellet (a cylindrical shape) may be cut in a prescribed size and fixed in the sealed space of the package 90.

While the sealing member is made of aluminum foil in each of the first, fifth and sixth embodiments, in the present invention, the sealing member may be formed by employing Cu foil, Cu alloy foil such as nickel silver, Sn foil, stainless steel foil or the like as metal foil other than aluminum foil, for example. The sealing member is preferably formed by a metal plate having high heat radiation properties, so that heat generated by the semiconductor laser chip(s) can be easily radiated outward.

While the base portion is sealed in a state where the sealant 15 is formed on the back surface of the sealing member in each of the first and sixth embodiments, in the present invention, the sealing member may be formed by employing polyamide resin, epoxy resin or the like other than metal, for example and mounted on the base portion through the sealant 15 arranged on the back surface. When the aforementioned resin materials are employed as the sealing member, EVOH resin (sealant 15) having excellent gas barrier properties can more effectively inhibit low molecular siloxane, volatile organic gas or the like from entering the package.

While the sealing member is made of a nickel silver sheet in each of the second and third embodiments, in the present invention, the sealing member may be formed by employing an aluminum plate, a Cu plate, an alloy plate such as Sn, Ni and Mg, a stainless steel plate, a ceramic sheet or the like other than the nickel silver sheet, for example.

While the cap portion 430 is made of kovar with an Ni-plated surface in the fourth embodiment, the present invention is not restricted to this, but the cap portion may be formed by employing Fe with an Ni-plated surface or the like.

Further, multilayer metal oxide films (dielectric films) of Al₂O₃, SiO₂, ZrO₂ and the like may be formed as gas barrier layers on surfaces of the window member also in each of the fourth to sixth embodiments. Alternatively, metal films of Al, Ni, Pt, Au or the like may be formed. Metal films may be formed on surfaces of a lead frame resin member in each of the first, second and sixth embodiments.

While the sealant 15 is applied onto one surface of the sealing member in a state where the sealing member is heated to about 220° C. in the manufacturing process of each of the first to third, fifth and sixth embodiments, in the present invention, the sealing member may be heated to remove solvent after a mixture of the solvent and EVOH resin prepared by dissolving the EVOH resin in the solvent is applied to the sealing member.

While the base body 10a is made of polyamide resin in each of the first and second embodiments, in the present invention, the base portion may be made of epoxy resin, polyphenylene sulfide resin (PPS), a liquid crystal polymer (LCP) or the like. LCP is suitable for a molding resin material for the base portion in that LCP is smaller in water absorption than the aforementioned other resin. At this time, the base body 10a can be molded in a state of a mixture obtained by introducing a gas absorbent into the resin material at a prescribed ratio. The gas absorbent is preferably prepared from a granular absorbent having a particle diameter of at least several 10 μm and not more than several 100 μl.

While the depth of the recess portion 10b of the base portion 10 is about half the thickness t1 of the base body 10a in each of the first and second embodiments, the present invention is not restricted to this, but the depth of the recess portion 10b may be deeper or shallower than the thickness t1/2, for example.

While the side surface of the sealant 15 bonding the base portion 315 and the sealing and window members 45 and 46 to each other is covered with the covering agent 18 in the modification of the third embodiment, and the side surface of the sealant 15 bonding the cap portion 430 and the light transmission portion 35 to each other is covered with the covering agent 18 in each of the fourth embodiment and the modification thereof, the present invention is not restricted to this, but a side surface of the sealant 15 bonding the sealing member and the window member in another embodiment to each other may be covered with this covering agent 18. An oxide film of SiO₂, Al₂O₃ or the like or a metal thin film of Al, Ni, Pb, Au or the like other than epoxy resin can be employed as a material with low water vapor permeability, for example.

While the covering agent 16 is applied onto the surfaces of the members located in the sealed space of the package 90 in each of the first, second and fourth to seventh embodiments, in the present invention, the covering agent 16 may not be applied.

While the optical pickup 800 has been shown in the eighth embodiment, the present invention is not restricted to this, but the semiconductor laser apparatus of the present invention may be applied to an optical disc apparatus performing record in and playback of an optical disc such as a CD, a DVD or a BD. Further, an RGB three-wavelength semiconductor laser apparatus may be constituted by red, green and blue semiconductor laser chips, and this RGB three-wavelength semiconductor laser apparatus may be applied to an optical apparatus such as a projector.

What is claimed is:

1. A semiconductor laser apparatus comprising:
a semiconductor laser chip; and
a package sealing said semiconductor laser chip, wherein
said package has a base portion mounted with said semiconductor laser chip, a sealing member and a window member through which light emitted from said semiconductor laser chip penetrates an outside thereof,
said semiconductor laser chip is sealed with said base portion, said sealing member and said window member, and
at least two of said base portion, said sealing member and said window member are bonded to each other through a sealant made of an ethylene-polyvinyl alcohol copolymer.

2. The semiconductor laser apparatus according to claim 1, wherein
said sealing member and said window member are bonded to each other through said sealant.

3. The semiconductor laser apparatus according to claim 1, wherein
said sealing member is made of metal.

4. The semiconductor laser apparatus according to claim 1, wherein
said sealing member is made of glass.

5. The semiconductor laser apparatus according to claim 1, wherein
said sealing member is made of metal foil and bonded to said base portion through said sealant in a bonded region, and
said sealant extends to a surface of said sealing member other than said bonded region.

6. The semiconductor laser apparatus according to claim 5, wherein
said base portion has an opening which opens from an upper surface to a front surface,
said sealing member is made of said metal foil having a side cross section bent in a substantially L-shaped manner from said upper surface to said front surface, and
said sealant is provided on a substantially entire surface of said sealing member facing sealed space of said package.

7. The semiconductor laser apparatus according to claim 1, wherein
a bonded region of at least two of said base portion, said sealing member and said window member is filled up with said sealant not to generate a hole penetrating from an inside of sealed space to an outside thereof.

8. The semiconductor laser apparatus according to claim 7, wherein
said sealant has a portion protruding from said bonded region into sealed space of said package, and
a thickness of protruding said portion is larger than a thickness of said sealant in said bonded region.

9. The semiconductor laser apparatus according to claim 8, wherein
said portion of said sealant protruding into said sealed space covers a surface of said base portion in the vicinity of said bonded region.

10. The semiconductor laser apparatus according to claim 2, wherein
said window member is bonded onto a surface of said sealing member in sealed space of said package or a surface of said sealing member in an outside of said package opposite to said sealed space through said sealant.

11. The semiconductor laser apparatus according to claim 1, wherein
a side surface of said sealant is covered with resin made of a material having smaller water vapor permeability than said sealant.

12. The semiconductor laser apparatus according to claim 1, wherein
said sealing member is in the form of a cylinder having a bottom portion.

13. The semiconductor laser apparatus according to claim 1, wherein
said base portion is made of a metal plate and includes a first lead frame,
said base portion has a recess portion in said metal plate other than said first lead frame, and
said semiconductor laser chip is mounted on an inner bottom surface of said recess portion.

14. The semiconductor laser apparatus according to claim 13, wherein
said first lead frame conducts with said inner bottom surface,
the semiconductor laser apparatus further comprising a second lead frame passing through a posterior surface of said recess portion backward beyond said semiconductor laser chip with respect to a laser beam-emitting direction and insulated from said inner bottom surface by an insulating member, wherein
said sealant is provided in the vicinity of at least a portion of said second lead frame mounted on said insulating member in sealed space of said package.

15. The semiconductor laser apparatus according to claim 1, wherein
a thickness of said sealant is at least 5 μm and not more than 50 μm.

16. The semiconductor laser apparatus according to claim 1, wherein
said semiconductor laser chip is a nitride-based semiconductor laser chip.

17. A method of manufacturing a semiconductor laser apparatus comprising steps of:
mounting a semiconductor laser chip on a base portion; and
bonding at least two of said base portion, a sealing member and a window member to each other through a sealant made of an ethylene-polyvinyl alcohol copolymer by thermocompression bonding so as to seal said semiconductor laser chip.

18. The method of manufacturing a semiconductor laser apparatus according to claim 17, wherein
said step of bonding includes a step of press-bonding said sealing member and at least one of said base portion and said window member to each other through said sealant after melted said sealant is applied to said sealing member.

19. The method of manufacturing a semiconductor laser apparatus according to claim 17, wherein
said step of bonding includes a step of press-bonding said sealing member and at least one of said base portion and said window member to each other in a state where said sealant formed in the form of a thin film is sandwiched therebetween.

20. An optical apparatus comprising:
a semiconductor laser apparatus including a semiconductor laser chip and a package sealing said semiconductor laser chip; and
an optical system controlling a beam emitted from said semiconductor laser apparatus, wherein
said package has a base portion mounted with said semiconductor laser chip, a sealing member and a window member through which light emitted from said semiconductor laser chip penetrates an outside thereof,
said semiconductor laser chip is sealed with said base portion, said sealing member and said window member, and
at least two of said base portion, said sealing member and said window member are bonded to each other through a sealant made of an ethylene-polyvinyl alcohol copolymer.
